(19) United States
(12) Patent Application Publication
(10) Pub. No.: US 2024/0250110 A1
(43) Pub. Date: Jul. 25, 2024

(54) IMAGE SENSORS WITH A TUNABLE FLOATING DIFFUSION STRUCTURE

(71) Applicant: KLA Corporation, Milpitas, CA (US)

(72) Inventors: Abbas Haddadi, San Jose, CA (US); Devis Contarato, San Carlos, CA (US); John Fielden, Los Altos, CA (US); Yung-Ho Alex Chuang, Cupertino, CA (US)

(21) Appl. No.: 18/404,530

(22) Filed: Jan. 4, 2024

Related U.S. Application Data
(60) Provisional application No. 63/440,674, filed on Jan. 23, 2023.

(51) Int. Cl. H01L 27/148

(52) U.S. Cl. CPC H01L 27/14856

(57) ABSTRACT

Image sensors with a tunable floating diffusion (FD) structure for applications such as inspection and metrology are provided. One image sensor includes a sensing node electrically connected to circuits of the image sensor, formed on a first side of a silicon layer adjacent to the circuits, and formed by a Voltage-Controlled Variable Floating Diffusion (VCVFD) structure. The VCVFD structure includes a gate electrode configured to control a variable capacitance of the VCVFD structure via voltage applied to the gate electrode by an electrical connection to the gate electrode. The VCVFD structure converts a charge responsive to electron accumulation in the channel of the circuits to a voltage proportional to an amount of the charge and dependent on the variable capacitance. The VCVFD may also be implemented in an electron-sensor pixel configured for detecting electrons or x-rays as described further herein.

### BACKGROUND OF THE INVENTION

### 1. Field of the Invention

This invention generally relates to image sensors with a tunable floating diffusion structure (also referred to herein as a sensing node), particularly suitable for use in charge-coupled devices (CCDs) for applications such as inspection and metrology.

### 2. Description of the Related Art

The following description and examples are not admitted to be prior art by virtue of their inclusion in this section.

Fabricating semiconductor devices such as logic and memory devices typically includes processing a substrate such as a semiconductor wafer using a large number of semiconductor fabrication processes to form various features and multiple levels of the semiconductor devices. For example, lithography is a semiconductor fabrication process that involves transferring a pattern from a photomask to a resist arranged on a semiconductor wafer. Additional examples of semiconductor fabrication processes include, but are not limited to, chemical-mechanical polishing (CMP), etch, deposition, and ion implantation. Multiple semiconductor devices may be fabricated in an arrangement on a single semiconductor wafer and then separated into individual semiconductor devices.

The integrated circuit industry requires inspection tools that provide increasingly higher sensitivity to detect smaller defects and particles, while maintaining high throughput for a lower cost of ownership. The semiconductor industry is currently manufacturing semiconductor devices with feature dimensions around 20 nanometers (nm) and smaller. Within a few years, the industry will be manufacturing devices with feature dimensions around 5 nm. Particles and defects just a few nm in size can reduce wafer yields and must be captured to ensure high-yield production. Furthermore, efforts have been spent on speeding up inspection to cope with the possible transition from today's 300 mm diameter wafers to 450 mm diameter wafers in the future. Thus, the semiconductor industry is driven by ever greater demand for inspection tools that can achieve substantially high sensitivity at substantially high speed.

An image sensor is a key component of a semiconductor inspection tool. It plays an important role in determining defect detection sensitivity and inspection speed. Considering their image quality, light sensitivity, and readout noise performance, charge-coupled-devices (CCDs) are widely used as image sensors for semiconductor inspection applications. The signal-to-noise-ratio (SNR) and dynamic range (DR) are important figures of merit for CCD image sensors. SNR describes the sensor's ability to detect a light signal above a certain noise-limited background, while the DR quantifies the sensor's ability to adequately image both high light and low light scenes.

An image sensor typically includes a reverse-biased pn-junction operated as a capacitor to convert the collected charge, generated by incident radiation or electrons, into a voltage, that then may be buffered and/or amplified and converted to a digital signal. This reverse-biased pn-junction is referred to herein as the Floating Diffusion (FD) region. The capacitance of the image sensor FD region defines the upper and lower limits of detectable optical signals and, subsequently, the dynamic range of CCD image sensors. Having a relatively small FD capacitance reduces the lower limit of the optical signal detection level (since a smaller capacitance results in a higher signal voltage per unit of charge collected), so that smaller signals can be detected; however, it comes at the price of reducing the maximum detectable signal. Using a larger FD capacitance increases the maximum detectable signal but reduces the sensitivity of the image sensor to low-level optical signals. Therefore, a need arises for a CCD image sensor implementing a tunable FD that facilitates relatively high dynamic range to improve an inspection system and overcome all the above limitations.

Accordingly, it would be advantageous to develop image sensors that do not have one or more of the disadvantages described above.

### SUMMARY OF THE INVENTION

The following description of various embodiments is not to be construed in any way as limiting the subject matter of the appended claims.

One embodiment relates to an image sensor that includes a silicon layer configured to generate electron-hole pairs when light is incident on a light-sensitive area of the silicon layer. The image sensor also includes circuits formed on a first side of the silicon layer. The circuits include a channel and first gate electrodes configured to control electron accumulation in the channel in response to light-induced generation of the electron-hole pairs.

The image sensor further includes a sensing node electrically connected to the circuits, formed on the first side of the silicon layer adjacent to the circuits and outside of the light-sensitive area, and formed by a Voltage-Controlled Variable Floating Diffusion (VCVFD) structure. The VCVFD structure includes a source region and a channel region. The source region of the VCVFD structure is connected to the channel of the circuits and to an output circuit of the image sensor. The VCVFD structure also includes a second gate electrode adjacent to the source region and configured to control a variable capacitance of the VCVFD structure via voltage applied to the second gate electrode by an electrical connection to the second gate electrode.

The VCVFD structure is configured to convert a charge responsive to the electron accumulation to a voltage proportional to an amount of the charge and dependent on the variable capacitance. The output circuit is configured to generate output responsive to the voltage output by the VCVFD structure. The image sensor may be further configured as described herein.

Another embodiment relates to a system configured for determining information for a specimen. The system includes an illumination subsystem configured for directing light generated by a light source to a specimen. The system also includes an image sensor positioned in a path of light from the specimen and configured as described above. The light incident on the light-sensitive area of the silicon layer is the light from the specimen. The system further includes a computer subsystem configured for determining information for the specimen based on the output generated by the output circuit of the image sensor. The system may be further configured as described herein.

A further embodiment relates to a computer-implemented method for determining information for a specimen. The method includes directing light generated by a light source to a specimen and detecting light from the specimen with an image sensor, which is configured as described further above. The light from the specimen is incident on a light-sensitive area of the image sensor. The method also includes determining information for the specimen based on the output, which is generated by an output circuit of the image sensor.

The steps of the method may be performed as described further herein. The method may include any other step(s) of any other method(s) described herein. The method may be performed by any of the systems described herein.

An additional embodiment relates to a non-transitory computer-readable medium storing program instructions executable on a computer system for performing a computer-implemented method for determining information for a specimen. The computer-implemented method includes the steps of the method described above. The computer-readable medium may be further configured as described herein. The steps of the computer-implemented method may be performed as described further herein. In addition, the computer-implemented method for which the program instructions are executable may include any other step(s) of any other method(s) described herein.

Some embodiments relate to an electron-sensor pixel that includes a silicon layer including: an n-type buried channel layer forming a first surface of the silicon layer and a p-type electron-sensitive layer disposed between the buried channel layer and an opposing second surface of the silicon layer. The silicon layer also includes a floating diffusion disposed in the buried channel layer adjacent to a central region of the pixel. The floating diffusion includes a sensing node formed by a VCVFD structure. The VCVFD structure includes a VCVFD source region and a VCVFD channel region. The VCVFD source region is connected to the channel of the pixel and an output circuit of the pixel. The VCVFD structure also includes a VCVFD gate electrode adjacent to the VCVFD source region and configured to control a variable capacitance of the VCVFD structure via voltage applied to the VCVFD gate electrode by an electrical connection to the VCVFD gate electrode. The VCVFD structure is configured to convert a charge responsive to electrons in the n-type buried channel layer moved toward the floating diffusion to a voltage proportional to an amount of the charge and depending on the variable capacitance.

The electron-sensor pixel also includes a resistive gate including at least one gate structure disposed over the first surface and configured such that an outer peripheral edge of the gate structure substantially aligns with an outer peripheral edge of the buried channel layer. The gate structure defines a central opening such that an inner peripheral edge of the gate structure substantially surrounds and is spaced from the central region. The buried channel layer and the p-type electron-sensitive layer are configured such that the p-type electron-sensitive layer creates multiple electrons in response to each incident electron or X-ray photon, and such that the created multiple electrons are driven into the buried channel layer. The resistive gate is configured such that, when a decreasing potential difference is applied between the inner peripheral edge and the outer peripheral edge of the gate structure, the resistive gate generates a first electric field that causes movement of electrons in the n-type buried channel layer toward the floating diffusion. The electron-sensor pixel may be further configured as described herein.

### BRIEF DESCRIPTION OF THE DRAWINGS

Other objects and advantages of the invention will become apparent upon reading the following detailed description and upon reference to the accompanying drawings in which:

FIG. 1A is a schematic diagram illustrating a side, cross-sectional view of an embodiment of a Voltage-Controlled Variable Floating Diffusion (VCVFD) structure;

FIG. 1B is a schematic diagram illustrating a top view of the VCVFD structure of FIG. 1A;

FIG. 2A is a schematic diagram illustrating a side, cross-sectional view of another embodiment of a VCVFD structure that includes a field-effect transistor (FET)-like structure with connected source and drain sections;

FIG. 2B is a schematic diagram illustrating a top view of the VCVFD structure of FIG. 2A;

FIG. 3 includes the schematic diagram of FIG. 1A with a profile of electrical potential versus distance into a semiconductor layer across and under the gate of a VCVFD structure;

FIG. 4 is a schematic diagram illustrating a side, cross-sectional view of an additional embodiment of an image sensor configured as a backside-illuminated charge-coupled device (CCD) that includes a VCVFD structure;

FIG. 5 is a schematic diagram illustrating a side view of an embodiment of a system configured for determining information for a specimen that includes a sensor configured as described herein;

FIGS. 6A-6C are schematic diagrams illustrating plan views of embodiments of an image sensor in which VCVFDs are electrically connected to different numbers of columns of pixels;

FIG. 7 is a block diagram illustrating one embodiment of a non-transitory computer-readable medium storing program instructions executable on a computer system for performing one or more of the computer-implemented methods described herein;

FIG. 8 illustrates an exemplary SEM incorporating a back-scattered electron detector and a secondary electron detector in accordance with an embodiment of the present invention;

FIG. 9 illustrates an exemplary method of inspecting or reviewing a sample;

FIGS. 10A, 10B, and 10C illustrate key aspects of an exemplary solid-state electron detector comprising multiple pixels with one output per pixel in accordance with an embodiment of the present invention;

FIGS. 11A and 11B illustrate in exploded and assembled front/top perspective views a single pixel electron sensor according to an exemplary specific embodiment of the present invention;

FIGS. 12A and 12B are simplified cross-sectional views showing the pixel of FIG. 11B during operation;

FIG. 13 is a simplified plan view showing an exemplary layout for an amplifier utilized by a pixel according to an alternative embodiment of the present invention; and

FIG. 14 is a simplified plan view showing a pixel layout according to another alternative embodiment of the present invention.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents, and alternatives falling within the spirit and scope of the present invention as defined by the appended claims.

### DETAILED DESCRIPTION OF THE PREFERRED EMBODIMENTS

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals. Unless otherwise noted herein, any of the elements described and shown may include any suitable commercially available elements.

The embodiments described herein generally relate to image sensors such as charge-coupled devices (CCDs) with a tunable floating diffusion (FD) structure for applications such as inspection and metrology. More specifically, the embodiments relate to the FD capacitance of image sensors such as CCDs, and more particularly to voltage-tunable FD capacitance. In addition, the embodiments described herein provide improvements in CCD image sensors for semiconductor inspection systems to enable relatively high dynamic range using a Voltage-Controlled Variable Floating Diffusion (VCVFD) structure. The terms “floating diffusion” and “sensing node” are used interchangeably herein.

Currently, the FD region is formed as an n+ implant in a semiconductor layer. This configuration enables the implementation of standard transistors adjacent to the FD (such as the transfer transistor and reset transistor). The use of the n+ implant to form the FD also provides a good ohmic contact between a contact plug and the FD. However, this arrangement only provides a fixed pn-junction capacitance, which cannot be changed after fabrication of the CCD image sensor.

A variable FD can be made by including several fixed FD areas in parallel on an image sensor chip. An array of switches or pass transistors can selectively couple the parallel fixed FD areas to a sensor output circuit. Electronic signals can be applied to the gates of a subset or all of the pass transistors to electronically connect the selected fixed FD areas to the sensor output. Other electronic signals can turn off other pass transistors, disconnecting their fixed FD areas from the sensor output. As more of the parallel fixed FD areas are connected to the sensor output, the capacitance increases. Thus, the total capacitance attached to the sensor output can be electronically selected. One disadvantage of this approach is that at least one switch must be connected directly to the sensor output. The capacitance of this switch and its connection to the sensor output will add to the capacitance of a FD connected to the sensor output, limiting the smallest FD capacitance achievable, hence limiting the sensitivity of such a CCD to substantially low light levels.

While such a switch-controlled variable FD may be useful in situations where sensitivity to substantially low light levels is not required, a variable FD controlled by an analog voltage can be a more compact and desirable choice for CCD image sensors suitable for use in semiconductor inspection systems. A variable FD that changes its capacitance value based on an applied voltage can allow for a wider range of capacitances, rather than a limited quanta of capacitances selected by binary control signals. What is desired is an analog voltage-controlled variable capacitor that can be integrated in CCD image sensors manufactured in common CCD processes.

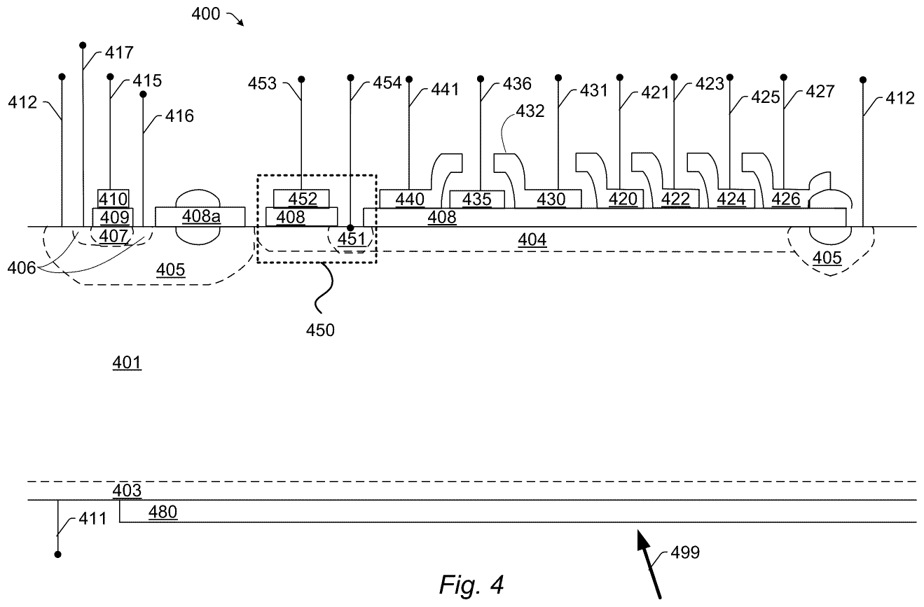

One embodiment of an image sensor includes a silicon layer configured to generate electron-hole pairs when light is incident on a light-sensitive area of the silicon layer. FIG. 4 illustrates some aspects of the design, fabrication, and operation of image sensor 400 configured as a backside-illuminated CCD image sensor implementing VCVFD structure 450. When light 499 is absorbed in the silicon, electron-hole pairs are created. In this manner, light 499 is incident on the backside of image sensor 400 (also referred to herein as the “second side”), which is opposite to the frontside (also referred to herein as the “first side”) of the image sensor on which the circuits of the image sensor are formed. The light-sensitive area of the sensor may include, for example, the entire area of the sensor on which the image sensor circuits (or pixels) are formed. The silicon layer may be configured to generate the electron-hole pairs in any suitable manner known in the art.

In one embodiment, the silicon layer is a silicon epitaxial layer. In one such embodiment, the silicon epitaxial layer includes intrinsic or p-type doped silicon with a dopant concentration less than 10¹⁴ cm⁻³. For example, the epitaxial layer may be manufactured on a highly doped p-type silicon substrate with a dopant concentration greater than about 10¹⁵ cm⁻³. As shown in FIG. 4, the sensor is fabricated in an intrinsic or lightly p-type doped epitaxial layer 401 with a thickness between a few micrometers and a few tens of micrometers.

In another such embodiment, the image sensor includes a thin p-type layer with a dopant concentration at least ten times higher than a dopant concentration of the silicon epitaxial layer, and the thin p-type layer is disposed on a second side of the silicon epitaxial layer opposite to a first side of the silicon layer. In backside-illuminated image sensors, the backside (light sensitive) surface of epitaxial layer 401 is where light 499 is incident. A substantially highly doped p+ layer 403 may be formed at the backside surface of epitaxial layer 401 by either ion implantation or drive-in of boron atoms from thin boron layers deposited on the surface. Backside p+ layer 403 is “thin” in that it may be substantially shallow (from a few nanometers to tens of nanometers) to ensure suitable sensitivity to ultraviolet (UV), deep UV (DUV), and vacuum UV (VUV) light. Under prolonged exposure to DUV or VUV light, charges and traps may accumulate in the silicon dioxide at the backside surface of epitaxial layer 401 and can degrade the sensor performance. Shallow p+ layer 403 introduces fixed negative charges on the sensor backside, which prevents trapping of the photogenerated charge at defects and preserves sensitivity to UV, DUV, and VUV light. Optional electrical connection 411 may be made to the backside p+ layer 403 and used to apply a bias voltage to the sensor backside (for example, to connect it to ground).

In an additional embodiment, the image sensor includes an antireflection layer disposed on a second side of the silicon layer opposite to the first side. For example, the antireflection layer may include backside coating 480 deposited on the back surface of epitaxial layer 401. Depending on the wavelengths of interest, backside coating 480 may be a substantially thin layer of pure boron or silicon dioxide, or one or more antireflection layers (e.g., made of alumina) to reduce the sensor reflectivity and improve sensitivity at those wavelengths. For example, in addition to the ranges of doping levels described herein, the backside optical coating may be custom-engineered to be highly sensitive to the wavelengths of interest of the systems described further herein in which the sensors may be used.

The image sensor also includes circuits formed on a first side of the silicon layer. The circuits include a channel and first gate electrodes configured to control electron accumulation in the channel in response to light-induced generation of the electron-hole pairs. For example, when light 499 is absorbed in the silicon, electron-hole pairs are created. Holes move to the backside surface where they recombine, while electrons are accelerated toward the channel formed by n-type layer 404 by the electric field generated across the sensor by the voltages applied to the gate electrodes on the frontside of the sensor, such as gates 420, 422, 424, and 426, which form a column of light-sensitive pixels. Although only four gates are shown for clarity purposes only, in preferred embodiments many more gates are used to form a substantially large number of light collecting pixels, from one pixel per column (e.g. a line sensor) to thousands of pixels.

Potential differences are applied to these gates via electrical connections 421, 423, 425, and 427 to control where (under which gate) the collected light-generated electrons are accumulated in n-type layer 404. Electrons will accumulate under the gate with the maximum potential underneath it. For example, if contact 427 connected to gate 426 is at a voltage of +5V and contact 425 connected to gate 424 is at a voltage of −5V, electrons will accumulate under gate electrode 426.

Other than controlling the storage of charge, the gates are used to transfer the stored charge from one pixel to another. For example, if electrons are stored under gate 426, raising the voltage on gate 424 applied by contact 425 to a more positive voltage than that applied to gate 426, and/or lowering the voltage on gate 426 applied by contact 427 to a smaller (more negative) voltage than that applied to gate 424, will move the electrons from gate 426 to underneath gate 424. The electrons can be subsequently moved from gate 424 to 422, from gate 422 to gate 420, and so on, by varying the voltages applied to electrodes 425, 423, and 421 appropriately.

As in CCD technology, the gates may be configured as two-phase, three-phase, or four-phase clocks (i.e., there are two, three, or four gates per pixel, respectively). Also, in a sensor suitable for semiconductor inspection such as a time-delay integration (TDI) sensor, the gates are clocked at a rate that causes the charge to be transferred in synchrony with a moving image falling on the sensor (such as in synchrony with the motion of the stage on which the specimen being inspected is held).

At one end of the light-sensitive pixel gates, for example, when electrons are underneath gate 420, electrons are moved to a first buffer gate such as 430 by applying a higher voltage to contact 431 connected to gate 430 compared to the voltage applied to contact 421 connected to gate 420. A more positive voltage than that applied to gate 430 (such as a few volts more positive) is then applied to second buffer gate 435 by contact 436, causing the electrons to move under second buffer gate 435. After this transfer, lowering the first buffer gate 430 to a voltage less than that applied by contact 421 to pixel gate 420 stops the transfer of electrons to the region under buffer gate 435, and allows accumulation of electrons from the next image pixel under buffer gate 430.

In preferred embodiments, sensor 400 may include additional gates similar to 440, each with an electrical connection such as 441, forming a readout register that transfers the image signals from the circuits (e.g., CCD pixels) to a VCVFD sensing node such as 450 for charge to voltage conversion. The number of additional gates may vary from a few to a few tens (typically from 2 to 32) depending on the application for which the sensor will be used. The electrons are transferred from one gate to another of the readout register by sequencing the voltages applied to the gates appropriately, as is done in CCDs. In another embodiment, there may be no readout register and gate 440 may be omitted, and electrons may be transferred directly to a VCVFD structure, which may be configured as described further herein.

In one embodiment, the channel of the circuits includes an n-type doped buried channel. For example, n-type layer 404, with a dopant concentration of about 10¹⁶ cm⁻³, may be formed just under the top (frontside) surface of epitaxial layer 401. When the sensor is properly biased, layer 404 forms a buried channel that is used to collect and transfer electrons as described above. At either end of the n-type layer 404 may be p+ type layer 405 which has a dopant concentration greater than or equal to about 2× the dopant concentration of the n-type layer. p+ layer 405 is connected to ground by one or more electrical contacts such as 412, and it may be connected to ground in multiple locations.

Dielectric layer 408 is formed (e.g., grown) on the front surface of the epitaxial layer. The dielectric layer may include a single dielectric material such as silicon dioxide, multiple layers of dielectric materials such as a silicon nitride layer on top of a silicon dioxide layer, or a three-layer stack such as silicon dioxide on silicon nitride on silicon dioxide. Suitable dielectric thicknesses range from about 50 nm to about 200 nm. Dielectric layer 408 may have openings etched into it as appropriate to allow electrical contact to the underlying silicon when needed. Multiple gate electrodes, which may be made of polysilicon, such as 420, 422, 424, 426, 430, 435, and 440 are formed (e.g., deposited and patterned) on top of dielectric layer 408. The gate electrodes are separated from each other by dielectric material (not shown). Electrical connections such as 421, 423, 425, 427, 431, 436, and 441 may be made to the gate electrodes. In preferred embodiments, the gate electrodes overlap one another, as shown for example at 432, to control fringe electric fields near the edges of the electrodes.

In one embodiment, the image sensor is configured as a CCD. In another embodiment, the image sensor is configured as a backside-illuminated CCD. In some embodiments, the circuits are configured as CCD circuits. In an additional embodiment, the circuits are configured as metal-oxide semiconductor field-effect transistors (MOSFETs). For example, the image sensor described herein may be configured as a backside-illuminated CCD image sensor implementing a VCVFD structure. As described further above, the image sensor may include CCD pixels and circuits on the front side of an intrinsic or lightly p-type doped silicon epitaxial layer and may incorporate a pure boron layer on its backside (illuminated) surface. Electrons generated by light at near-infrared (near-IR), visible, UV, DUV, VUV, extreme UV (EUV), and/or X-ray wavelengths are detected in the epitaxial layer and collected by the CCD pixels on the front side of the epitaxial layer due to the electric field generated across the epitaxial layer by appropriate voltages applied to the CCD pixels. The electrons collected by the CCD pixels are transferred to a VCVFD structure configured for performing charge-to-voltage conversion and connected to CCD readout circuits. As described further herein, the sensor embodiments may be configured as CCD sensors for semiconductor wafer, reticle, and printed circuit board (PCB) inspection.

In a further embodiment, the image sensor is configured as a CCD configured to function as a time-delay integration (TDI) sensor. For example, the sensor embodiments described herein may be a CCD sensor used as a TDI sensor for wafer, reticle, PCB, etc. inspection. Such an image sensor may be configured so that the gates are clocked at a rate that causes the charge to be transferred in synchrony with a moving image falling on the sensor (such as in synchrony with the motion of the stage on which the specimen being inspected is held). Such an embodiment of the sensor as well as a system in which the sensor may be used may be further configured as described in U.S. Pat. No. 9,620,547 to Chuang et al. issued Apr. 11, 2017, which is incorporated by reference as if fully set forth herein. For example, the sensors described herein may be configured as CCD sensors with internal avalanche multiplication as described in this patent.

The image sensor further includes a sensing node electrically connected to the circuits. For example, as shown in FIG. 4, the image sensor includes sensing node 450 connected to the circuits (e.g., formed by gate electrodes 420, 422, 424, 426, 430, 435, and 440). The sensing node may be electrically connected to the circuits as described further herein.

The sensing node is formed on the first side of the silicon layer adjacent to the circuits and outside of the light-sensitive area. In this manner, the sensing node is adjacent to one or more gate electrodes, e.g., CCD gate electrodes such as gate electrodes 420, 422, 424, 426, 430, 435, and 440, and receives the signal charge from them. Therefore, the embodiments described herein are different from complementary metal-oxide-semiconductor (CMOS) image sensor pixels, where a VCVFD structure would have to be embedded in every pixel. In other words, in a CMOS device, the VCVFD structure would have to be formed in the light-sensitive area of the device, while in many of the embodiments described herein, the VCVFD structure can advantageously be formed outside of the light-sensitive area as shown in FIG. 4.

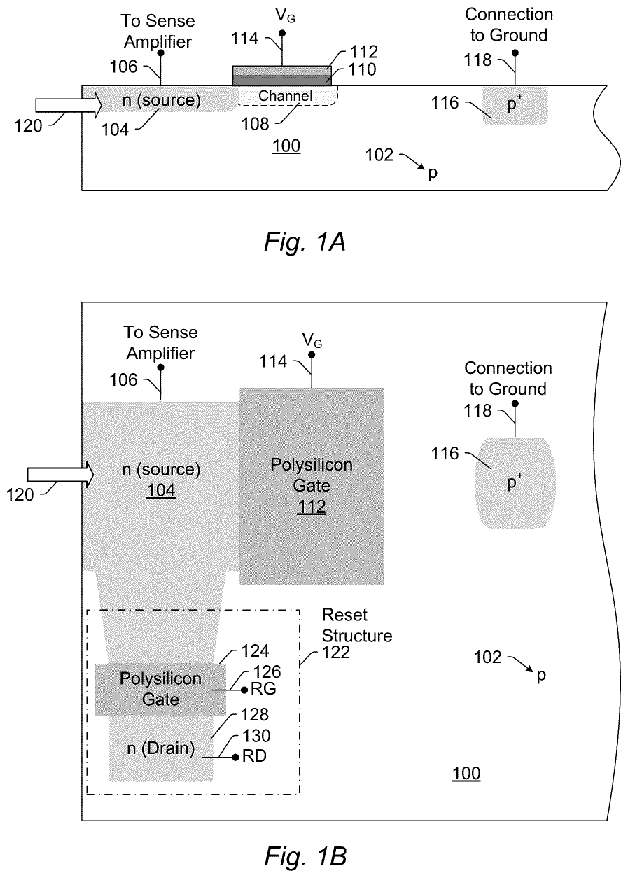

The sensing node 450 is formed by a VCVFD structure. FIGS. 1A and 1B show side and top views, respectively, of a basic VCVFD structure implemented on a silicon layer. The VCVFD structure includes source region 104 and channel region 108. As shown in FIGS. 1A and 1B, one end of silicon layer 100 underneath the polysilicon gate is doped with n-type impurities, with concentrations several orders of magnitude higher than the silicon layer p-type doping 102, e.g., ranging from 10¹⁸ to 10²⁰ atoms per cubic centimeter, to form a pn-junction for source 104 of the VCVFD structure. The source of the VCVFD structure is electrically connected to a sense amplifier (e.g., by electrical connection 106) that buffers the voltage signal corresponding to the charge stored in the VCVFD capacitance to the image sensor output.

The source region of the VCVFD structure is connected to the channel of the circuits (not shown in FIGS. 1A and 1B) and an output circuit (not shown in FIGS. 1A and 1B) of the image sensor. The source region of the VCVFD structure may be connected to the channel as described further herein and shown in FIG. 4. As described further herein, source 104 may be connected to the channel of the circuits so that the VCVFD structure receives charge 120 from the sensor circuits.

In one embodiment, the source region of the VCVFD structure is connected to a charge reset structure in the image sensor. For example, source 104 may be connected to adjacent reset structure 122 shown in FIG. 1B, formed by polysilicon gate 124 to which a Reset Gate (RG) voltage is applied via electrical connection 126 and n-type drain 128 to which a fixed Reset Drain (RD) voltage is applied by electrical connection 130. After the voltage signal at the VCVFD source is read out by the sense amplifier, the RG gate is biased to connect the VCVFD source to the RD voltage, typically higher than the VCVFD source voltage, so that charge is drained from the VCVFD source. The VCVFD structure is thus reset to the RD voltage. When reset is complete, the VCVFD source is disconnected from the RD voltage, so that it can receive the next charge signal from the circuits of the image sensor.

In one embodiment, the source region of the VCVFD structure and the channel of the circuits are doped with the same polarity, and the source region of the VCVFD structure has a dopant concentration equal to or higher than a dopant concentration in the channel of the circuits. For example, as shown in FIG. 4, VCVFD structure 450 may include source 451 formed by a n+ type silicon region implanted and/or diffused into epitaxial layer 401. The dopant concentration of source 451 is typically a few orders of magnitude higher than n-type layer 404, e.g., ranging from 10¹⁸ cm⁻³ to 10²¹ cm⁻³.

In another embodiment, the channel region of the VCVFD structure and the channel of the circuits are doped with the same polarity. For example, both the channel region of the VCVFD structure and the channel of the circuits may be n-type channels. The VCVFD channel and the channel of the circuits may be formed in the same step or steps and may have the same or different dopant concentrations. In the same manner as the circuits, therefore, the VCVFD structure can be either of the surface channel type or the buried channel type. For example, in some embodiments, the channel region of the VCVFD structure is configured as an n-type buried channel. In another embodiment, the channel region of the VCVFD structure is configured as an n-type surface channel. In this manner, the gate electrode of the VCVFD structure may be one of an n-type buried channel and an n-type surface channel.

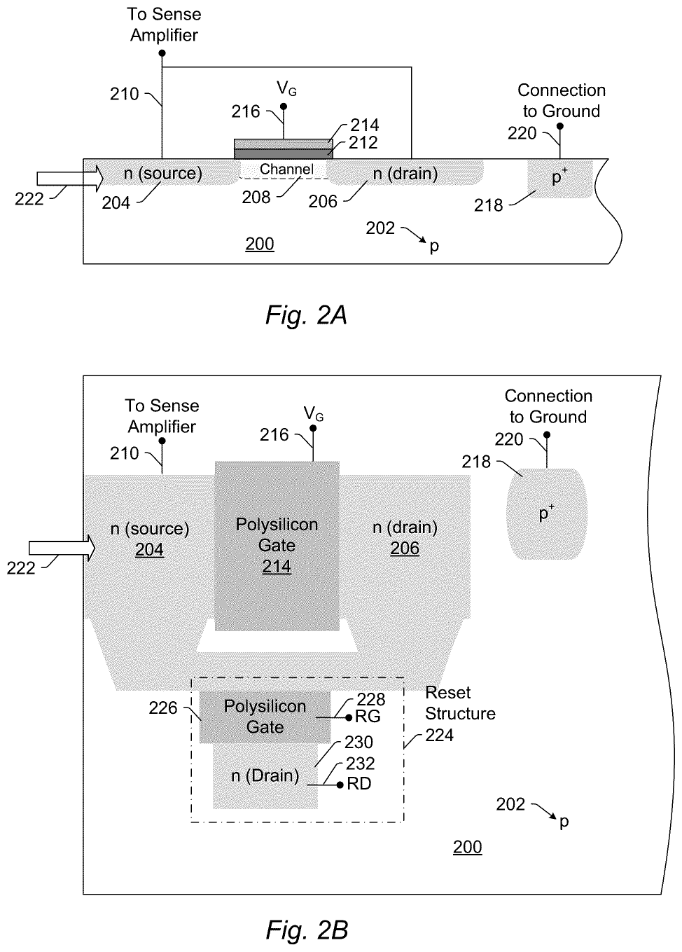

The VCVFD structure also includes a VCVFD gate electrode (also referred to herein as a “second gate electrode”) adjacent to the source region. For example, VCVFD gate electrode 452 shown in FIG. 4 can be formed using the same polysilicon material as the CCD pixel gates (for example, gates 420, 422, 424, and 426) and using the same dielectric layer 408, or using different electrode and dielectric materials. As illustrated in FIG. 4 (and more clearly in FIG. 1A and described further herein), VCVFD gate 452 is typically adjacent to source 451 and may be slightly overlapping it. Also similar to CCDs, VCVFD structure 450 may be provided with a reset transistor (not shown in FIG. 4) adjacent to the VCVFD source and connected to a fixed reset voltage. The reset transistor may be used to reset the VCVFD structure prior to transferring the electrons from the pixels as described further herein. The VCVFD structure shown in FIG. 4 may be connected to a charge reset structure as further shown and described in FIGS. 1B and 2B.

The VCVFD gate electrode is configured to control a variable capacitance of the VCVFD structure via voltage applied to the VCVFD gate electrode by an electrical connection to the VCVFD gate electrode. For example, gate 452 is provided with electrical connection 453 via which the voltage applied to the VCVFD gate can be controlled. In this manner, the VCVFD structure may be configured as an analog VCVFD structure for image sensors such as CCD image sensors using a Metal-Oxide-Semiconductor (MOS) structure that includes a gate and a source. When the gate-to-source voltage (V_{G}) of the MOS structure is above the threshold voltage (V_{T}), the charge may be stored in the MOS inversion layer and in the source-bulk pn-junction capacitor. The total capacitance of this FD structure can be controlled via an analog gate voltage.

As shown in FIG. 1A, the VCVFD gate electrode of the VCVFD structure may include polysilicon gate 112 separated from silicon layer 100 by a relatively thin layer of oxide dielectric (i.e., gate oxide) 110. The polysilicon gate is provided with electrical connection 114, through which voltage V_{G} may be applied to the VCVFD gate, thus forming a MOS structure. The lateral dimensions of this polysilicon gate may vary from a few micrometers to tens of micrometers, depending on the desired VCVFD capacitance. The thickness of the oxide dielectric layer may vary from a few nanometers to tens of nanometers and may be determined by the CCD image sensor manufacturing process and the desired VCVFD capacitance.

p+ ohmic contact 116 shown in FIG. 1A may be formed by locally implanting higher densities of p-type impurities at the surface of the silicon layer. The p+ ohmic contact may have electrical connection 118 to connect the silicon layer to ground potential.

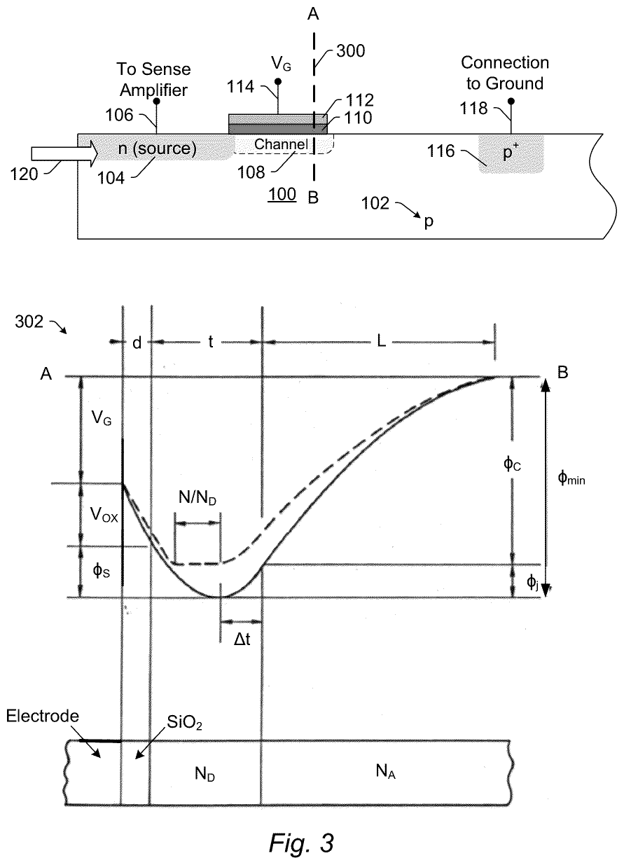

FIG. 3 shows profile 302 of electrostatic potential versus distance across line 300 (from point A to point B) through the polysilicon gate, the oxide dielectric, and into the semiconductor layer under the gate of the VCVFD structure embodiment of FIG. 1A. The total capacitance of the VCVFD structure is

$${C}_{VCVFD} ( {V}_{G} ) = {C}_{S} + {C}_{Gate} ( {V}_{G} )$$

where C_{S} is the capacitance of the VCVFD source that represents the minimum C_{VCVFD}, typically determined by the capacitance of the pn-junction constituting the VCVFD source and its parasitic capacitances (for example, due to the overlap of nearby CCD gates with the VCVFD source and to the interconnection between the VCVFD source and the CCD sense amplifier), and C_{Gate} is the additional capacitance due to the VCVFD gate, which is controlled by the voltage V_{G} applied to the gate itself. With reference to FIG. 3, and using the analysis performed in Barbe et al., “A Tradeoff Analysis of Transfer Speed Versus Charge-Handling Capacity for CCD's,” Technology and Applications of CCDs Workshop, Edinburgh, Scotland, 1974, which is incorporated by reference as if fully set forth herein, under the assumption that the buried channel is depleted of charge by the application of a relatively large positive voltage, it can be shown that, for a buried channel field-effect transistor (FET)-based VCVFD, C_{Gate} is determined by

$$\frac{1}{{C}_{Gate}} = \frac{d}{{ε}_{OX}} + \frac{t}{{ε}_{S}} ( 1 - \frac{Δ t}{t} - \frac{1}{2} \cdot \frac{N}{{N}_{D} t} ) ,$$

where

$$Δ t = {( \frac{2 {ε}_{S}}{q} \cdot \frac{{N}_{A}}{{N}_{D} ( {N}_{D} + {N}_{A} )} {ϕ}_{min} )}^{1 / 2} ,$$

and d, ε_{OX}, ε_{S}, and t are the thickness of the oxide layer, oxide dielectric constant, silicon dielectric constant, and thickness of the buried channel layer, respectively. N is the minority carrier density collected underneath the gate, while N_{A} and N_{D} are the acceptor and donor concentrations in the silicon layer, respectively, and

$${ϕ}_{min} = {ϕ}_{c} + {ϕ}_{j} = {ϕ}_{min} ( {V}_{G} )$$

is the potential at the minimum of the buried channel layer, dependent on the voltage V_{G} applied to the VCVFD gate. The equations above can be used for a surface channel FET-based VCVFD structure as well by setting t to zero, so that

$${C}_{Gate} = {C}_{OX} = \frac{{ε}_{OX}}{d}$$

is the gate oxide capacitance per unit area, and where N_{D}/(N_{D}+N_{A}) ϕₘᵢₙ is replaced by the gate surface potential ϕs. For a surface-channel FET-based VCVFD structure, the C_{Gate} capacitance is proportional to the gate voltage swing. It increases with increasing gate voltage, but at relatively high gate voltages it may be ultimately limited by either surface avalanche breakdown or the oxide breakdown effect. For a buried-channel FET-based VCVFD, the capacitance may be limited by the gate voltage swing or by the doping characteristics of the buried channel.

The VCVFD structure is configured to convert a charge responsive to the electron accumulation to a voltage proportional to an amount of the charge and dependent on the variable capacitance. For example, the VCVFD structure converts the charge of the electrons to a voltage proportional to the amount of charge and dependent on the total capacitance of the VCVFD structure, determined by the sum of the fixed capacitance of the VCVFD source and the variable capacitance of the VCVFD gate, controlled by the voltage applied to electrode 453 shown in FIG. 4. In this manner, during operation, the charge collected from the (e.g., CCD) imaging elements (pixels) is transferred to the VCVFD structure and stored in its source-bulk pn-junction capacitor. When the polysilicon gate voltage V_{G} is below the threshold voltage V_{T} of the MOS structure it forms with the oxide dielectric and the silicon layer, charge stored in channel 108 under the polysilicon gate is substantially small. On the other hand, when the polysilicon gate voltage V_{G} is above the threshold voltage V_{T} of the MOS structure, charge is also stored in the channel under the polysilicon gate, in addition to the source-bulk pn-junction capacitor.

A VCVFD structure as described in FIGS. 1A and 1B can be formed using the same polysilicon gate and dielectric oxide materials as the pixel and charge transfer gates of an image sensor, and the polysilicon gate may be placed adjacent to a standard pn-junction FD region and slightly overlapping with it. The image sensor gates can be either of the surface channel type or the buried channel type. A VCVFD structure as described in FIGS. 1A and 1B can also be formed by the source and gate of a “partial” FET device, with the drain missing. The partial FET structure can be either of the enhancement mode (surface channel) type or of the depletion mode (buried channel) type. In preferred embodiments, the CCD gates and the partial FET structure used to form a VCVFD structure are of the buried channel type, which is a better choice for use in CCD image sensors to avoid charge transfer and noise performance issues typical of surface channel devices.

In another embodiment, the VCVFD structure includes a drain region connected to the channel region of the VCVFD structure, and the source region and the drain region of the VCVFD structure are electrically connected. FIGS. 2A and 2B show side and top views, respectively, of an alternative implementation of a VCVFD structure formed by n-type source 204 and drain 206 of a FET on a p-type 202 silicon layer 200. Source region 204 and drain region 206 are formed on either side of channel 208 above which polysilicon gate 214 is formed. The lateral dimensions of polysilicon gate 214 may vary from a few micrometers to tens of micrometers, depending on the desired VCVFD capacitance. The polysilicon gate is separated from silicon layer 200 by a relatively thin layer of oxide dielectric 212 (i.e., gate oxide). The thickness of the oxide dielectric layer may vary from a few nanometers to tens of nanometers and may be determined by the CCD image sensor manufacturing process and the desired VCVFD capacitance. The polysilicon gate is provided with electrical connection 216, through which voltage V_{G} may be applied to the VCVFD gate.

As in FET manufacturing processes, the impurity concentrations of the source and drain regions typically range from 10¹⁶ to 10²⁰ atoms per cubic centimeter and are several orders of magnitude higher than in the silicon layer. The FET structure can be either of the enhancement mode (surface channel) type or of the depletion mode (buried channel) type. In preferred embodiments, the FET structure is of the depletion mode (buried channel) type, which as noted above is a better choice for CCD image sensors' charge transfer and noise performance. Therefore, in most of the embodiments described herein, the VCVFD structure is configured with only a source (or connected source and drain) and a gate with a buried channel underneath. Also, an n-type source region (or connected n-type source and drain regions) in a p-type silicon layer is used for most of the VCVFD embodiments described herein, but the concepts described herein apply equally to p-type sources (or connected p-type source and drain regions) in n-type silicon layers.

In the embodiment shown in FIGS. 2A and 2B, the FET source and drain regions are electrically connected and can be viewed as two VCVFD structures connected in parallel to a sense amplifier by electrical connection 210. The source region of the VCVFD structure is also connected to the channel of the circuits and an output circuit (not shown in FIGS. 2A and 2B) of the image sensor. As described further herein, source 204 may be connected to the channel of the circuits so that the VCVFD structure receives charge 222 from the sensor circuits.

In one embodiment, the source region of the VCVFD structure is connected to a charge reset structure in the image sensor. For example, adjacent reset structure 224 shown in FIG. 2B may be connected to both the source and drain regions, so that charge can be drained from both regions during the reset operation happening between consecutive charge signal readout operations. Adjacent reset structure 224 shown in FIG. 2B is formed by polysilicon gate 226 to which an RG voltage can be applied via electrical connection 228 and n-type drain 230 to which a fixed RD voltage can be applied via electrical connection 232. The charge reset structure may be further configured as described herein.

The VCVFD structure shown in FIGS. 2A and 2B may be further configured as described herein. For example, p+ ohmic contact 218 may be formed by locally implanting higher densities of p-type impurities at the surface of the silicon layer. The p+ ohmic contact may have electrical connection 220 to connect the silicon layer to ground potential.

The image sensor's output circuit is configured to generate output responsive to the voltage output by the VCVFD structure. The output circuit may be included in (or be one of) multiple circuits configured for amplifying and/or processing the signals generated by the sensor and controlling the sensor, and these circuits may be fabricated inside the light-sensitive area or adjacent to the light-sensitive area. In FIG. 4, source 451 is provided with electrical connection 454 to connect it to the CCD readout circuits, typically formed by MOSFET transistors such as those described above. The VCVFD output voltage on connection 454 in FIG. 4 may be connected to a buffer or amplifier before being connected to the CCD output or an Analog-to-Digital Converter (ADC).

Such a circuit is illustrated in FIG. 4 by the MOSFET transistor formed by source and drain implants 406, channel implant 407, gate dielectric 409, and gate electrode 410. Electrical connections such as 415, 416, and 417 may be made to the MOSFET transistor's gate, source, and drain, respectively. Gate dielectric 409 may be substantially similar to dielectric layer 408 and may be formed at the same time, or gate dielectric 409 may be formed of different materials and/or different thicknesses than dielectric layer 408 depending on, for example, the desired transistor characteristics. Even though only one such transistor is illustrated in FIG. 4 for clarity purposes only, typically such circuits include many transistors. In preferred embodiments, MOSFET transistors with a n-type channel are fabricated in a p+ doped well 405 to electrically isolate them from dark currents and photocurrents in epitaxial material 401.

Structure 408a may also be substantially similar to dielectric layer 408 and may be formed at the same time, e.g., as a single dielectric layer that is then patterned to create separation between dielectric layer 408 and structure 408a. Alternatively, structure 408a may be formed of different materials and/or different thicknesses than dielectric layer 408 and/or gate dielectric 409 depending on, for example, the desired characteristics of structure 408a. Structure 408a may be an optional isolation structure formed between VCVFD structure 450 and the output circuit and may be formed above p well 405. In this manner, the isolation structure may separate the readout circuits from the sensor active area and the VCVFD structure.

In some embodiments, the circuits are configured as a two-dimensional (2D) array of pixels. For example, in CCD image sensors suitable for semiconductor inspection systems, multiple columns of pixels such as those described in FIG. 4 are laid out to form a 2D array of light-sensitive pixels. Clock signals are connected across the whole array and used to transfer charge from one pixel to the next within all, or a group of, columns simultaneously. However, the sensor pixels could be laid out in different configurations from those shown, and may include more or fewer pixels than shown.

In another embodiment, the circuits are configured as multiple columns of pixels that include at least first and second columns of pixels, the at least first and second columns of pixels include one or more pixels, the sensing node is one of multiple sensing nodes in the image sensor, the multiple sensing nodes include at least first and second sensing nodes, and the first and second sensing nodes are electrically connected to all of the one or more pixels in the first and second columns of pixels, respectively. More specifically, each of the sensing nodes may be electrically connected to only the first (or last) pixel in each of the columns. If a column includes more than one pixel, then the first pixel is connected to the second pixel, the second pixel is connected to the third, and so on. As such, a sensing node may be directly connected to one pixel in a column and connected to other pixels in the same column via that one pixel. In this manner, the sensor may include a VCVFD structure for each column of pixels. More specifically, a first VCVFD structure may be electrically connected to all of the pixels in only a first column of pixels, a second VCVFD structure may be electrically connected to all of the pixels in only a second column of pixels different than the first, and so on. Each of the VCVFD structures may be configured as described herein. In this manner, the structures shown in FIG. 4 may form one column of pixels electrically connected to one VCVFD structure, and the image sensor may include multiple sets of these structures arranged side by side on the sensor.

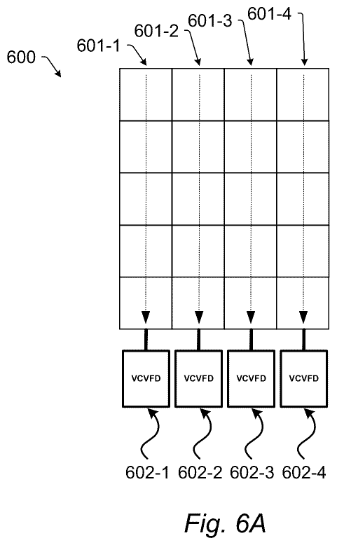

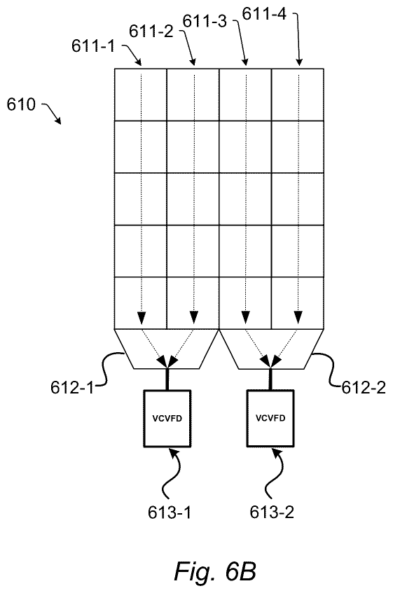

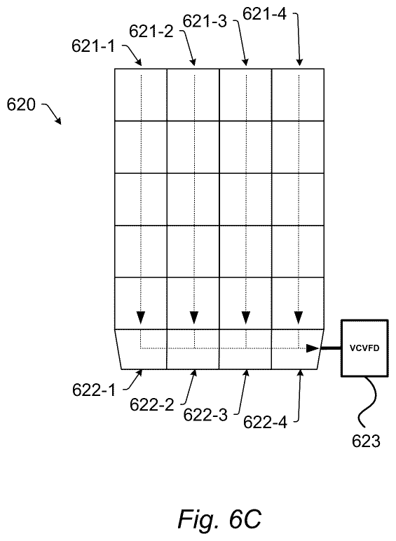

A more detailed view of such an image sensor is shown in FIG. 6A. Image sensor 600 includes four columns of pixels 601-1, 601-2, 601-3, and 601-4. Although four columns of pixels are shown in this figure, the sensor may include one or more such columns of pixels. In addition, although each of the columns shown in FIG. 6A includes five pixels, each column may include one or more pixels. As shown in FIG. 6A, VCVFD 602-1 is electrically connected to the first or last pixel in column 601-1 and is therefore connected to all of the pixels in that column and none of the pixels in any other of the columns. In a similar manner, VCVFD 602-2 is electrically connected to all of the pixels in only column 601-2, VCVFD 602-3 is electrically connected to all of the pixels in only column 601-3, and VCVFD 602-4 is electrically connected to all of the pixels in only column 601-4. Each of the VCVFD structures may have the same configuration as each other VCVFD structure. The image sensor may therefore include many more pixel circuits than VCVFD structures. For example, in each column of transistors or circuits, there may be one or more pixel circuits (even tens or hundreds of pixel circuits) and only one VCVFD structure. This configuration provides advantages described further herein.

In a further embodiment, the circuits are configured as multiple columns of pixels that include at least first and second columns of pixels, the at least first and second columns of pixels include one or more pixels, and the sensing node is electrically connected to the one or more pixels in the first and second columns of pixels. In other words, the sensor may include a VCVFD structure that is common to a group of two or more columns of pixels. One such embodiment of an image sensor is shown in FIG. 6B. In this embodiment, image sensor 610 includes four columns that each include five pixels. The number of columns and the number of pixels in each column may vary as described above. In this embodiment, VCVFD 613-1 is electrically connected to all of the pixels in only columns 611-1 and 611-2, and VCVFD 613-2 is electrically connected to all of the pixels in only columns 611-3 and 611-4. VCVFDs 613-1 and 613-2 may have the same configuration as each other and may be further configured as described herein. The image sensor may also include elements 612-1 and 612-2, which may include buffer gates, readout registers, etc., such as buffer gates 430 and 435 and readout register gate 440 shown in FIG. 4. Therefore, the VCVFDs may be electrically connected to these elements and thereby each of the pixels connected thereto. In this manner, a VCVFD structure may be provided to a group of columns read out simultaneously.

In addition, a single VCVFD structure may be electrically connected to the pixels in more than two columns. For example, a first VCVFD structure may be electrically connected to all of the pixels in first, second, and third columns, and a second VCVFD structure may be electrically connected to all of the pixels in fourth, fifth, and sixth columns. In this manner, the structures shown in FIG. 4 may form one of multiple columns of pixels electrically connected to one VCVFD structure, and the image sensor may include multiple sets of this combination of structures arranged side by side on the sensor. One such embodiment of an image sensor is shown in FIG. 6C. In this embodiment, image sensor 620 includes four columns that each include five pixels. The number of columns and the number of pixels in each column may vary as described above. In this embodiment, VCVFD 623 is electrically connected to all of the pixels in only columns 621-1, 621-2, 621-3, and 621-4, which may be all of the columns of pixels in the image sensor or only a portion of the pixel columns in the sensor (in which case, the image sensor may include more than one of the configuration shown in FIG. 6C). VCVFD 623 may be further configured as described herein. The image sensor may also include elements 622-1, 622-2, 622-3, and 622-4, which may include buffer gates, readout registers, etc., such as buffer gates 430 and 435 and readout register gate 440 shown in FIG. 4. Therefore, the VCVFDs may be electrically connected to these elements and thereby each of the pixels connected thereto.

If any image sensor configuration described herein includes more than one VCVFD structure, each of the VCVFD structures may have the same configuration as each other VCVFD structure. In addition, each VCVFD structure included in such an image sensor configuration may be further configured as described herein. Similar to the configuration described above and shown in FIG. 6A, the image sensors shown in FIGS. 6B and 6C may include many more pixel circuits than VCVFD structures. For example, in each two or more columns of transistors or circuits, there may be one or more pixel circuits (even tens or hundreds of pixel circuits) and only one VCVFD structure. These configurations also provide advantages described further herein.

In some embodiments, only one or two VCVFD structures, connected to output circuits, may be used. For example, in preferred embodiments suited for use in substantially high-speed inspection systems such as those used in the semiconductor industry, multiple VCVFD structures and their corresponding outputs (such as several tens of outputs, a few hundred outputs, one output per every column, or one output per every two columns) may be used to simultaneously output multiple pixels in order to achieve a substantially high data output rate. Such sensors may include a 2D array of about 1000 or a few thousand columns, between a few hundred and a few thousand pixels long. Such sensors may be configured as described further herein.

In some embodiments, the circuits are configured as pixels that include at least first and second pixels, the sensing node is electrically connected to the first and second pixels, and the image sensor or a computer subsystem is configured to calibrate the sensing node thereby calibrating the first and second pixels. In this manner, the embodiments described herein may be configured so that calibration of the pixels can be done by calibrating each sensing node rather than the pixels. In other words, by calibrating a sensing node, each pixel electrically connected to that sensing node can be effectively calibrated. For example, if a sensing node is coupled to all of the pixels in a column, the calibration response or sensitivity in that one column should all be the same. Therefore, since the image sensors described herein will most likely include substantially fewer sensing nodes than pixels, e.g., thousands of sensing nodes vs. millions of pixels, the embodiments described herein can calibrate each of the pixels faster and easier via calibration of the sensing nodes but not the pixels themselves. Other than calibrating the sensing nodes rather than the pixels themselves, the calibration may be performed by the image sensor or the computer subsystem in any suitable manner known in the art. The computer subsystem may be further configured as described herein.

In contrast to some of the embodiments described above in which each column includes multiple pixels, the image sensor embodiments described herein may include a single pixel in each column. This image sensor may therefore include a single line of pixels with each column of pixel circuits including only a single pixel circuit. Each single pixel circuit may be formed by only one CCD gate, although it may have multiple electrodes connected to it to control the voltage applied across the gate and the potential in the CCD channel below the gate. Examples of such a sensor pixel configuration are described in U.S. Pat. No. 9,620,547 to Chuang et al. issued Apr. 11, 2017, and U.S. Pat. No. 10,194,108 to Chuang et al. issued Jan. 29, 2019, which are incorporated by reference as if fully set forth herein. The image sensors described herein may be further configured as described in these patents.

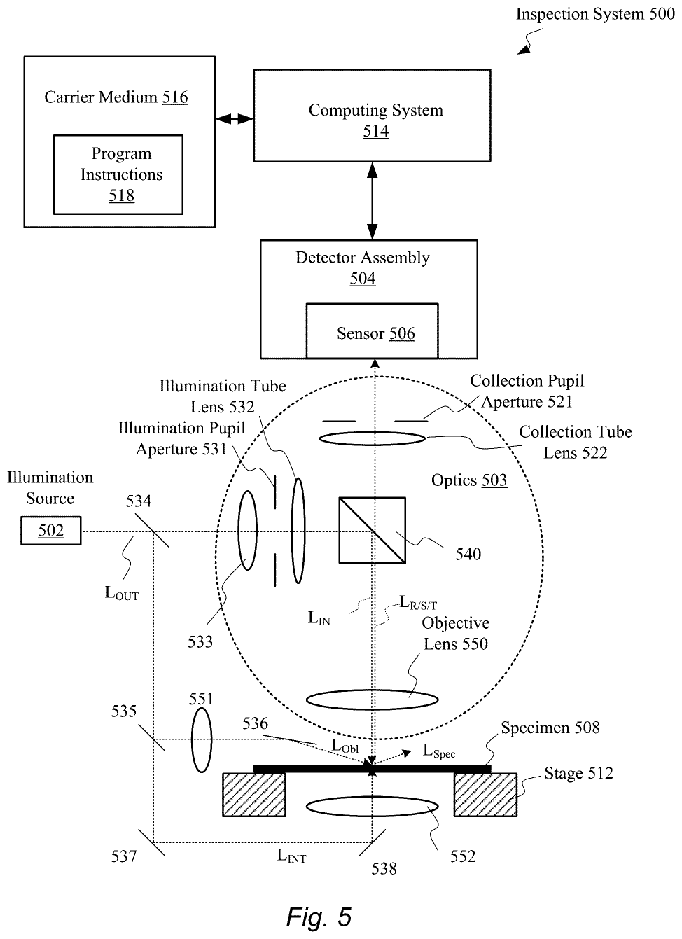

In another embodiment, the image sensor is positioned in an inspection system so that the light incident on the light-sensitive area is light from a specimen being inspected by the inspection system, and the inspection system is configured for detecting defects on the specimen based on the output generated by the output circuit of the image sensor. This embodiment may be configured as described further herein and shown in FIG. 5.

Another embodiment relates to a system configured for determining information for a specimen. FIG. 5 shows an exemplary inspection system 500 configured to inspect or make measurements on specimen 508, in accordance with one or more embodiments described herein. Inspection system 500 may be configured as an inspection system or a metrology system that inspects and/or makes measurements on specimen 508.

Specimen 508 may be a wafer. The wafer may include any wafer known in the semiconductor arts. The embodiments are also not limited in the specimen for which they can be used. For example, the embodiments described herein may be used for specimens such as reticles, photomasks, flat panels, printed circuit boards (PCBs), and other semiconductor specimens.

Specimen 508 may be disposed on stage assembly 512 to facilitate movement of specimen 508. Stage assembly 512 may include any stage assembly known in the art including, but not limited to, an X-Y stage, an R-θ stage, and the like. In another embodiment, stage assembly 512 is capable of adjusting the height of specimen 508 during inspection to maintain focus on specimen 508. In yet another embodiment, a lens such as objective lens 550 may be moved up and down during inspection to maintain focus on specimen 508.

The system includes an illumination subsystem configured for directing light generated by a light source to a specimen. The illumination subsystem may include illumination source 502 that generates output light L_{OUT} having a wavelength in a range between, for example, approximately 120 nm and approximately 2000 nm. Illumination source 502 may light sources such as a laser or a broadband light source. In addition, illumination source 502 may include any other suitable light source known in the art.

The illumination subsystem may include one or more optical components such as beam splitters, mirrors, lenses, apertures and waveplates that are configured to condition and direct light L_{OUT} to specimen 508. The optical components may be configured to illuminate an area, a line, or a spot on specimen 508. In one embodiment of the illumination subsystem, beam splitter or mirror 534, mirrors 537 and 538, and lens 552 are configured to illuminate specimen 508 from below so as to enable inspection or measurement of specimen 508 by transmitting light LINT through the specimen. The illumination subsystem may also or alternatively include beam splitters or mirrors 534 and 535, mirror 536, and lens 551 configured to illuminate specimen 508 with light at an oblique angle of incidence L_{Obl}, for example, an angle of incidence greater than 60° relative to a normal to the specimen surface. In this embodiment, the specularly reflected light L_{Spec} may be blocked or discarded rather than collected.

The illumination subsystem may also or alternatively include optics 503 collectively configured to direct illumination light LIN to the top surface of specimen 508. For example, the illumination subsystem may include lens 533, illumination pupil aperture 531, illumination tube lens 532, beam splitter 540, and objective lens 550 of optics 503 that collectively direct light from the light source to the specimen at an angle of incidence, which may be, for example, a normal or substantially normal angle of incidence. Illumination tube lens 532 may be configured to image illumination pupil aperture 531 to a pupil within objective lens 550. For example, illumination tube lens 532 may be configured such that illumination pupil aperture 531 and the pupil within objective lens 550 are conjugate to one another. Illumination pupil aperture 531 may be configurable by switching different apertures into the location of illumination pupil aperture 531 and/or by adjusting a diameter or shape of the opening of illumination pupil aperture 531. In this regard, specimen 508 may be illuminated by different ranges of angles depending on the characterization (e.g., measurement or inspection) being performed under control of computing system 514. Illumination pupil aperture 531 may also include a polarizing element (not shown) to control the polarization state of the illumination light LIN.

The system also includes a sensor 506 positioned in a path of the light from the specimen. The sensor is configured as described further herein. The light from the specimen is incident on a light-sensitive area of the image sensor. For example, when specimen 508 is illuminated in one or more of the above-described modes, optics 503 is also configured to collect light, L_{R/S/T}, reflected, scattered, diffracted, transmitted and/or emitted from specimen 508, and direct and focus the light L_{R/S/T} to sensor 506 of detector assembly 504. Sensor 506 and detector assembly 504 may include any sensor embodiment described further herein. Detector assembly 504 is communicatively coupled to computing system 514.

Computing system 514 is configured to store and/or analyze data from detector assembly 504 under control of program instructions 518 stored on carrier medium 516. Computing system 514 may be configured to control other elements of inspection system 500 such as stage 512, illumination source 502, and optics 503.

Optics 503 may include collection tube lens 522. Collection tube lens 522 may be configured to image the pupil within objective lens 550 to collection pupil aperture 521. For instance, collection tube lens 522 may be configured such that collection pupil aperture 521 and the pupil within objective lens 550 are conjugate to one another. Collection pupil aperture 521 may be configurable by switching different apertures into the location of collection pupil aperture 521 and/or by adjusting a diameter or shape of the opening of collection pupil aperture 521. In this regard, different ranges of angles of illumination reflected or scattered from specimen 508 may be directed to detector assembly 504 under control of computing system 514. Collection pupil aperture 521 may also include a polarizing element (not shown) so that a specific polarization of light L_{R/S/T} can be selected for transmission to sensor 506.

Illumination pupil aperture 531 and/or collection pupil aperture 521 may include a programmable aperture. Programmable apertures are generally discussed in U.S. Pat. No. 9,255,887 to Brunner issued on Feb. 9, 2016, and U.S. Pat. No. 9,645,287 to Brunner issued on May 9, 2017, both of which are herein incorporated by reference in the entirety. Methods of selecting an aperture configuration for inspection are generally described in U.S. Pat. No. 9,709,510 to Kolchin et al. issued on Jul. 18, 2017, and U.S. Pat. No. 9,726,617 to Kolchin et al. issued on Aug. 8, 2017, both of which are herein incorporated by reference in the entirety. The embodiments described herein may be further configured as described in these patents.

The various optical elements and operating modes depicted in FIG. 5 are merely to illustrate how sensor 506 may be used in inspection system 500 and are not intended to limit the scope of the present disclosure. A practical inspection system 500 may implement a subset or a superset of the modes and optics depicted in FIG. 5. Additional optical elements and subsystems may be incorporated as needed for a specific application.

The system further includes a computer subsystem configured for determining information for the specimen based on output generated by an output circuit of the image sensor. For example, computing system 514 shown in FIG. 5 may be configured in this manner. Computing system 514 may be coupled to sensor 506 in any suitable manner (e.g., via one or more transmission media, which may include “wired” and/or “wireless” transmission media) such that the computing system can receive the output, images, etc. generated by sensor 506. Computing system 514 may be configured to perform a number of functions using the output of the sensor as described herein and any other functions described further herein. This computing system may be further configured as described herein.

The computing system may include one or more computer subsystems (not shown) that are configured to perform one or more functions such as determining the information for the specimen based on the output of the image sensor. The computer subsystem(s) of the computing system (as well as other computer subsystems described herein) may also be referred to herein as computer system(s). Each of the computing system(s) and computer subsystem(s) or system(s) described herein may take various forms, including a personal computer system, image computer, mainframe computer system, workstation, network appliance, Internet appliance, or other device. In general, the term “computer system” may be broadly defined to encompass any device having one or more processors, which executes instructions from a memory medium. The computing system(s) and computer subsystem(s) or system(s) may also include any suitable processor known in the art such as a parallel processor. In addition, the computing system(s) and computer subsystem(s) or system(s) may include a computer platform with high speed processing and software, either as a standalone or a networked tool.

If the system includes more than one computer subsystem, then the different computer subsystems may be coupled to each other such that images, data, information, instructions, etc. can be sent between the computer subsystems as described further herein. For example, two or more computer subsystems may be coupled to each other by any suitable transmission media (not shown), which may include any suitable wired and/or wireless transmission media known in the art. Two or more of such computer subsystems may also be effectively coupled by a shared computer-readable storage medium (not shown).

FIG. 5 is provided herein to generally illustrate some configurations of a system in which the sensor embodiments described herein may be included. Obviously, the system configurations described herein may be altered to optimize the performance of the system as is normally performed when designing a commercial system. In addition, the systems described herein may be implemented using an existing system (e.g., by adding the image sensor embodiments and other functionality described herein to an existing system) such as systems that are commercially available from KLA Corp., Milpitas, Calif. For some such systems, the embodiments described herein may be provided as optional functionality of the existing system (e.g., in addition to other functionality of the system). Alternatively, the system described herein may be designed “from scratch” to provide a completely new system.

The computer subsystem may be configured for determining the information in a number of different ways depending on, for example, the specimen, the optical system configuration, and the information being determined for the specimen. For example, in one embodiment, the system is configured as an inspection system, and the information for the specimen includes information for defects detected on the specimen based on the output. In one such example, computing system 514 may be configured for detecting defects on specimen 508 by applying a defect detection method to the output generated by sensor 506. Computing system 514 may be coupled to sensor 506 as described further herein so that it can receive the output generated by the sensor. Detecting defects on the specimen may be performed in any suitable manner known in the art (e.g., applying a defect detection threshold to the output and determining that any output having a value above the threshold corresponds to a defect (or a potential defect)) with any suitable defect detection method and/or algorithm.

In another embodiment, the system is configured as a metrology system. In a further embodiment, the system is configured as a defect review system. For example, the embodiment of the system shown in FIG. 5 may be modified in one or more parameters to provide different imaging capability depending on the application for which it will be used. In one such example, the system may be configured to have a higher resolution if it is to be used for metrology rather than for inspection. In other words, the embodiment of the system shown in FIG. 5 describes some general and various configurations for a system that can be tailored in a number of manners that will be obvious to one skilled in the art to produce systems having different imaging capabilities that are more or less suitable for different applications.

In this manner, the system may be configured for generating output that is suitable for re-detecting defects on the specimen in the case of a defect review system and for measuring one or more characteristics of the specimen in the case of a metrology system. In a defect review system embodiment, computing system 514 may be configured for re-detecting defects on specimen 508 by applying a defect re-detection method to the output generated by sensor 506 and possibly determining additional information for the re-detected defects using the output generated by the sensor. In a metrology system embodiment, computing system 514 may be configured for determining one or more characteristics of specimen 508 using the output generated by the sensor.

Defect review typically involves re-detecting defects detected as such by an inspection process and generating additional information about the defects at a higher resolution, e.g., using the system described herein in a high magnification mode. Defect review is therefore performed at discrete locations on the specimen where defects have been detected by inspection. The higher resolution data for the defects generated by defect review is generally more suitable for determining attributes of the defects such as profile, roughness, more accurate size information, etc. Computing system 514 may be configured to determine such information for defects on the specimen in any suitable manner known in the art.

Metrology processes are used at various steps during a semiconductor manufacturing process to monitor and control the process. Metrology processes are different than inspection processes in that, unlike inspection processes in which defects are detected on a specimen, metrology processes are used to measure one or more characteristics of the specimen that cannot be determined using currently used inspection tools. For example, metrology processes are used to measure one or more characteristics of a specimen such as a dimension (e.g., line width, thickness, etc.) of features formed on the specimen during a process such that the performance of the process can be determined from the one or more characteristics. In addition, if the one or more characteristics of the specimen are unacceptable (e.g., out of a predetermined range for the characteristic(s)), the measurements of the one or more characteristics of the specimen may be used to alter one or more parameters of the process such that additional specimens manufactured by the process have acceptable characteristic(s).

Metrology processes are also different than defect review processes in that, unlike defect review processes in which defects that are detected by inspection are re-visited in defect review, metrology processes may be performed at locations at which no defect has been detected. In other words, unlike defect review, the locations at which a metrology process is performed on a specimen may be independent of the results of an inspection process performed on the specimen. In particular, the locations at which a metrology process is performed may be selected independently of inspection results. In addition, since locations on the specimen at which metrology is performed may be selected independently of inspection results, unlike defect review in which the locations on the specimen at which defect review is to be performed cannot be determined until the inspection results for the specimen are generated and available for use, the locations at which the metrology process is performed may be determined before an inspection process has been performed on the specimen. Computing system 514 may be configured to determine any suitable characteristics for the specimen in any suitable manner known in the art.

In any of the system embodiments described herein, computing system 514 shown in FIG. 5 may be configured to generate results that include at least the information determined for the specimen based on the output generated by the image sensor possibly with any other output generated by the computing system. The results may have any suitable format (e.g., a KLARF file, which is a proprietary file format used by tools commercially available from KLA, a results file generated by Klarity, which is a tool that is commercially available from KLA, a lot result, etc.). In addition, all of the embodiments described herein may be configured for storing results of one or more steps of the embodiments in a computer-readable storage medium. The results may include any of the results described herein and may be stored in any manner known in the art. The storage medium may include any storage medium described herein or any other suitable storage medium known in the art. After the results have been stored, the results can be accessed in the storage medium and used by any of the method or system embodiments described herein, formatted for display to a user, used by another software module, method, or system, etc. to perform one or more functions for the specimen or another specimen.

Such functions include, but are not limited to, altering a process such as a fabrication process or step that was or will be performed on the specimen in a feedback, feedforward, in-situ manner, etc. For example, the computer subsystem may be configured to determine one or more changes to a process that was or will be performed on the specimen based on the detected defect(s) and/or other determined information. The changes to the process may include any suitable changes to one or more parameters of the process. For example, if the determined information is defects detected on the specimen, the computer subsystem preferably determines those changes such that the defects can be reduced or prevented on other specimens on which the revised process is performed, the defects can be corrected or eliminated on the specimen in another process performed on the specimen, the defects can be compensated for in another process performed on the specimen, etc. The computer subsystem may determine such changes in any suitable manner known in the art.

Those changes can then be sent to a semiconductor fabrication system (not shown) or a storage medium (not shown in FIG. 5) accessible to both the computer subsystem and the semiconductor fabrication system. The semiconductor fabrication system may or may not be part of the system embodiments described herein. For example, the systems described herein may be coupled to the semiconductor fabrication system, e.g., via one or more common elements such as a housing, a power supply, a specimen handling device or mechanism, etc. The semiconductor fabrication system may include any semiconductor fabrication system known in the art such as a lithography tool, an etch tool, a chemical-mechanical polishing (CMP) tool, a deposition tool, and the like.

Each of the embodiments of the systems described above may be further configured according to any other embodiment(s) described herein.

Another embodiment relates to a computer-implemented method for determining information for a specimen. The method includes directing light generated by a light source to a specimen. The method also includes detecting light from the specimen with an image sensor. The image sensor is configured as described further herein. For example, the light from the specimen is incident on a light-sensitive area of a silicon layer of the image sensor. The method further includes determining information for the specimen based on the output generated by an output circuit of the image sensor.

Each of the steps of the method may be performed as described further herein. The method may also include any other step(s) that can be performed by the system(s) described herein. The steps of the method may be performed by the systems described herein, which may be configured according to any of the embodiments described herein.

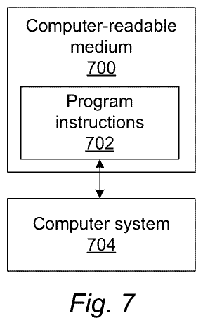

An additional embodiment relates to a non-transitory computer-readable medium storing program instructions executable on a computer system for performing a computer-implemented method for determining information for a specimen. One such embodiment is shown in FIG. 7. In particular, as shown in FIG. 7, non-transitory computer-readable medium 700 includes program instructions 702 executable on computer system 704. The computer-implemented method may include any step(s) of any method(s) described herein.

Program instructions 702 implementing methods such as those described herein may be stored on computer-readable medium 700. The computer-readable medium may be a storage medium such as a magnetic or optical disk, a magnetic tape, or any other suitable non-transitory computer-readable medium known in the art.

The program instructions may be implemented in any of various ways, including procedure-based techniques, component-based techniques, and/or object-oriented techniques, among others. For example, the program instructions may be implemented using ActiveX controls, C++ objects, JavaBeans, Microsoft Foundation Classes (“MFC”), SSE (Streaming SIMD Extension) or other technologies or methodologies, as desired.

Computer system 704 may be configured according to any of the embodiments described herein.

The VCVFD structures described above are particularly suitable for use in light-based systems such as those described above but may also be exemplary sensing nodes for sensors configured for other applications such as electron sensors or X-ray sensors. For example, the VCVFD structure described above may be incorporated into an electron-sensor pixel and an electron sensor as described below.

The resistive gate in the individual electron-sensor pixels described below is one important difference from conventional CMOS image sensor pixels. The electron-sensor pixels are sensitive to light (unless an opaque coating is applied), but their relatively large size means that they will not be useful in light-based inspection systems. The electric fields created by the resistive gate (when appropriate operating voltages are applied) are what enables the pixels to be reasonably fast (˜100 MHz readout rate) while being relatively large. Otherwise, the time for electrons to drift from one corner of the pixel to the sensing node would be too long for high-speed operation.

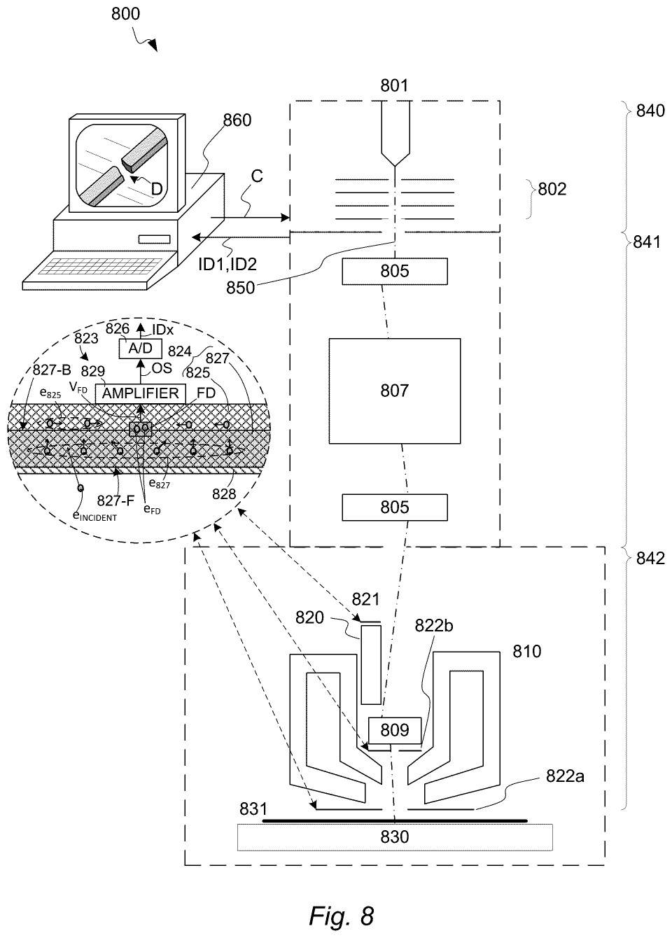

For electron sensor applications, for example a sensor integrated into an electron beam system similar to that depicted in FIG. 8 (described below), the sensor may be configured to detect electrons or X-rays. Relative to inspection systems using light, there are typically fewer incident signal electrons or X-ray photons per unit time, yet each incident electron or X-ray photon generates many (typically a few tens to a few thousand) electron-hole pairs when absorbed in silicon.

In one mode, individual arriving high-energy electrons (say about 1 keV or higher in energy) or X-ray photons (energies of a few hundred eV to around 20 keV-30 keV) are counted, and their energies are determined (approximately) from the number of electron-hole pairs produced (i.e., signal collected). In this mode, the floating diffusion capacitance is preferably relatively small, ideally just a few femtofarads (fF), so that substantially small signals can be measured with as little noise as possible.

In another mode, the signal from secondary electrons (typically 20 eV-50 eV in energy) is collected. Secondary electrons are more numerous than higher energy electrons and X-ray photons, but they generate only about 10 or fewer electron-hole pairs per incident electron. Depending on operating mode, if a relatively large signal is to be detected, a higher floating-diffusion capacitance may be preferred. The VCVFD allows the floating-diffusion capacitance to be changed according to the system operating mode.

In one embodiment of an electron-sensor pixel, the pixel includes a silicon layer including: an n-type buried channel layer forming a first surface of the silicon layer and a p-type electron-sensitive layer disposed between the buried channel layer and an opposing second surface of the silicon layer. Each of these elements may be configured as described below.

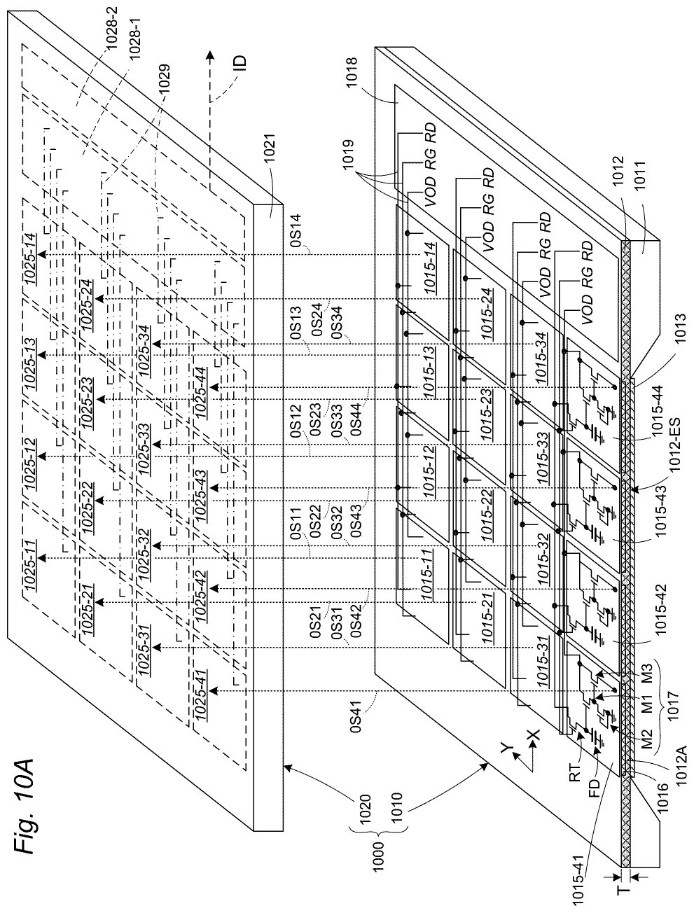

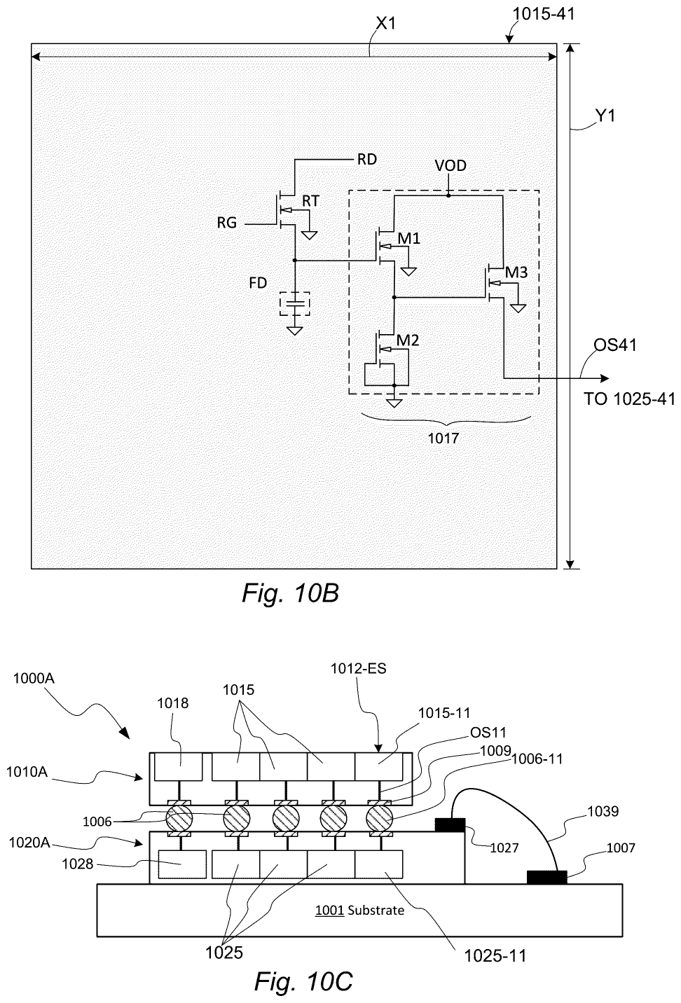

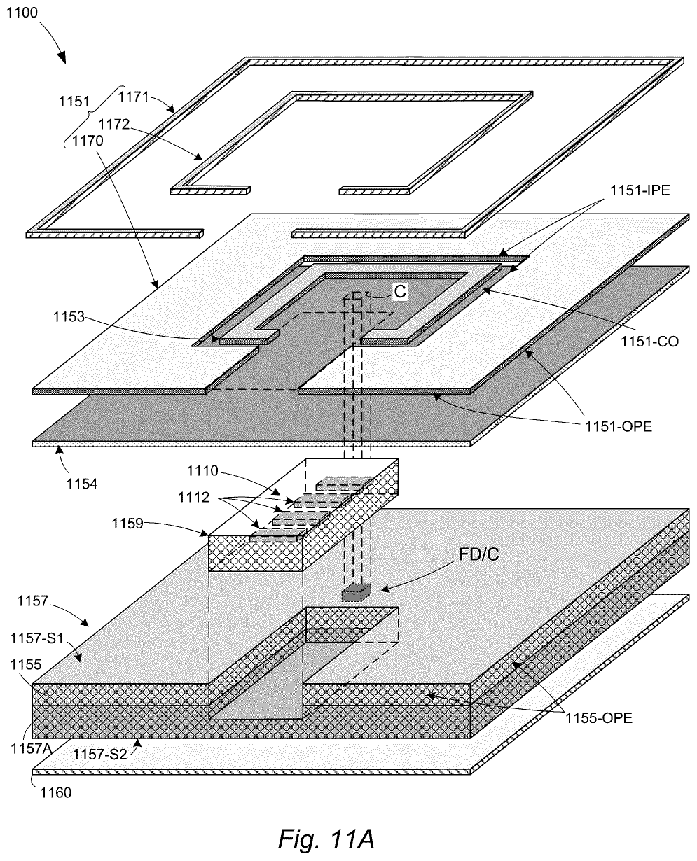

The silicon layer also includes a floating diffusion disposed in the buried channel layer adjacent to a central region of the pixel. The floating diffusion includes a sensing node formed by a VCVFD structure. The VCVFD structure includes a VCVFD source region and a VCVFD channel region. The VCVFD source region is connected to the channel of the pixel and an output circuit of the pixel. The VCVFD structure also includes a VCVFD gate electrode adjacent to the VCVFD source region and configured to control a variable capacitance of the VCVFD structure via voltage applied to the VCVFD gate electrode by an electrical connection to the VCVFD gate electrode. The VCVFD structure is configured to convert a charge responsive to electrons in the n-type buried channel layer moved toward the floating diffusion to a voltage proportional to an amount of the charge and depending on the variable capacitance. This VCVED structure may be configured as described further herein and shown in, for example, FIGS. 1A, 1B. 2A, and 2B. The VCVFD structure may be connected to the pixel as shown in FIG. 4. In addition, the VCVFD structure may be formed in floating diffusion FD shown in FIGS. 10A, 10B and 11A.

The electron-sensor pixel also includes a resistive gate including at least one gate structure disposed over the first surface and configured such that an outer peripheral edge of the gate structure substantially aligns with an outer peripheral edge of the buried channel layer. The gate structure defines a central opening such that an inner peripheral edge of the gate structure substantially surrounds and is spaced from the central region. The buried channel layer and the p-type electron-sensitive layer are configured such that the p-type electron-sensitive layer creates multiple electrons in response to each incident electron, and such that the created multiple electrons are driven into the buried channel layer. The resistive gate is configured such that, when a decreasing potential difference is applied between the inner peripheral edge and the outer peripheral edge of the gate structure, the resistive gate generates a first electric field that causes movement of electrons in the n-type buried channel layer toward the floating diffusion. The electron-sensor pixel may be further configured as described herein. These elements may also be configured as described herein.

The following description is incorporated herein from commonly owned U.S. Patent Application Publication No. 2016/0064184 by Brown et al. published Mar. 3, 2016, which is also incorporated by reference as if fully set forth herein. The embodiments of electron-sensor pixels, electron sensors, and electron beam systems described in this publication are exemplary of the types of pixels, sensors, and systems in which the VCVFD structures described herein may be incorporated. However, it is obviously conceivable that the VCVFD structures described herein may be used in electron-sensor pixels, electron sensors, and electron beam systems having other configurations known in the art. The embodiments described herein may be further configured as described in the above-referenced patent publication.

FIG. 8 illustrates an exemplary scanning electron microscope (SEM) 800, also referred to as an inspection or review system configured to inspect or review a sample 831 such as a semiconductor wafer, reticle, or photomask. SEM 800 generally comprises an electron gun (source) 840, electron optics including an upper column 841 and a lower column 842, a stage 830 for supporting and positioning a sample 831, and a system computer 860.

In one embodiment electron gun 840 comprises a cathode 801 such as a thermal field-emitting or Schottky cathode, a single-crystal tungsten cathode or a LaB6 cathode, and extraction and focusing electrodes 802. Electron gun 840 may further comprise a magnetic lens (not shown). Electron gun 840 generates a primary electron beam 850 with a desired beam energy and beam current.

Upper column 841 of the electron optics includes one or more condenser lenses 807 that de-magnify the primary beam to create a small spot on the sample 831. Generally spot sizes of about one to a few om are preferred for generating high-resolution images for review of samples. Inspection of a sample may use larger spot sizes in order to scan the sample 831 more quickly. A single condenser lens 807 may suffice when the spot size is of order 100 nm or larger, but two or more condenser lenses are typically needed for spot sizes of tens of nm or smaller. Condenser lens 807 may comprise a magnetic lens, an electrostatic lens or both. Upper column 841 may also include one or more deflectors 805 that scan the primary electron beam across an area of sample 831. Deflectors 805 may be placed on either side of condenser lens 807 as shown, or within the condenser lens 807 (not shown), or after the condenser lens 807. Deflectors 805 may comprise electrostatic deflectors or a combination of magnetic and electrostatic deflectors. In one embodiment, there may be no deflectors in the upper column 841. Instead all the deflectors may be contained in lower column 842.

Lower column 842 includes a final (immersion) lens 810 for focusing the primary electron beam to a small spot on the sample 831. Final lens 810 may comprise a magnetic lens (as shown) or a combination of a magnetic lens and an electrostatic lens (not shown). In order to achieve a small spot size at the sample 831, final lens 810 is placed close to the sample 831, so that the sample is immersed in the magnetic field of the lens. This can reduce aberrations in the electron spot on the sample 831. Lower column 842 also includes deflectors 809 that work in combination with deflectors 805 (if present) to scan the primary electron beam across an area of the sample 831.

Sample 831 is placed on a stage 830 in order to facilitate movement of different regions of sample 831 underneath the electron column. Stage 830 may comprise an X-Y stage or an R-θ stage, and in one embodiment is configured to support and position numerous sample types typically reviewed by the integrated circuit industry (e.g., an unpatterned semiconductor wafer, a patterned semiconductor wafer, a reticle, or a photomask). In preferred embodiments, stage 830 can adjust the height of sample 831 during inspection to maintain focus. In other embodiments, final lens 810 can be adjusted to maintain focus. In some embodiments, a focus or height sensor (not shown) may be mounted on or proximate to final lens 810 in order to provide a signal to adjust the height of sample 831 or to adjust the focus of the final lens 810. In one embodiment, the focus sensor or height sensor may be an optical sensor.

Secondary electrons and back-scattered electrons are emitted from an area of the sample 831 when the primary electron beam 850 is scanned by the electron optics across the area. Secondary electrons may be collected and accelerated by electrodes 820 and directed to secondary electron detector 821. Electron optics for collecting, accelerating and/or focusing secondary electrons are described in U.S. Pat. No. 7,141,791 to Masnaghetti et al., entitled “Apparatus and method for e-beam dark-field imaging”. This patent is incorporated by reference herein. As described in the '791 patent, the electron optics for the secondary electron detector may include de-scanning optics for, at least, partially canceling the effects of the deflectors 809 on the trajectories of the secondary electrons. In some embodiments of this invention the de-scanning electron optics are not needed and may be omitted, as the de-scanning may be approximately achieved by an ASIC included within the secondary electron detector as described herein. Secondary electron detector 821 is preferably a solid-state electron detector, such as one of the solid-state electron detectors described herein, and is configured to generate an image data signal ID2 in accordance with detected secondary electrons, wherein image data signal ID2 is transferred to computer 860 and utilized to generate an image of the associated scanned sample area, whereby visual inspection of a defect D is facilitated. Other electron optics and detector configurations and methods for detecting and analyzing secondary electrons that may be used in combination with the systems and methods described herein are described in U.S. Pat. No. 7,838,833, to Lent et al., entitled “Apparatus and method for e-beam dark imaging with perspective control”, and U.S. Pat. No. 7,714,287 to James et al., entitled “Apparatus and method for obtaining topographical dark-field images in a scanning electron microscope”. Both of these patents are incorporated by reference herein.

Back-scattered electrons may be detected by a back-scattered electron detector, such as those shown at 822a and 822b, which is implemented by one of the solid-state electron detectors described herein, and is configured to generate an image data signal ID1 in accordance with detected back-scattered electrons, where data signal ID1 is transferred to computer 860 and is also utilized to generate the image of the associated scanned sample area. Preferably the back-scattered electron detector is placed as close as possible to the sample 831, such as at location 822a (i.e., between final lens 810 and sample 831). However, the gap between the sample 831 and the final lens 810 may be small, such as about 2 mm or less, and clearance may be needed, for example, for a focus or height sensor, and so it may not be practical to place the back-scattered electron detector at location 822a. Alternatively, the back-scattered electron detector may be placed at location such as 822b, on the other side of the final lens 810 pole pieces from the sample 831. Note that the back-scattered electron detector must not block primary electron beam 850. The back-scattered electron detector may have a hole in the middle or may comprise multiple detectors (such as two, three or four separate detectors) disposed around the path of the primary electron beam 850 so as not to block that path, while being efficient for capturing back-scattered electrons.

The landing energy of the primary electron beam 850 on the sample 831 depends on the potential difference between the cathode 801 and the sample 831. In one embodiment, the stage 830 and sample 831 may be held close to ground potential, and the landing energy adjusted by changing the potential of the cathode 801. In another embodiment, the landing energy on the sample 831 may be adjusted by changing the potential of the stage 830 and sample 831 relative to ground. In either embodiment, the final lens 810 and the back-scattered electron detector 822a and/or 822b must all be at potentials close to one another and close to that of the sample 831 and stage 830 (such as less than about 1000V relative to the sample 831 and stage 830) in order to avoid arcing to the sample 831. Because of this small potential difference, back-scattered electrons from the sample 831 will be accelerated only a small amount, or not at all, from the sample to the back-scattered electron detector 822a and/or 822b. Since the landing energy on the sample 831 may be quite low (such as between about 500 eV and 2 keV) for some semiconductor samples in order to avoid damage to those samples, the energy of the back-scattered electrons as they land on the back-scattered electron detector 822a and/or 822b will be quite low. Thus, it is important for the sensitivity of the SEM that the back-scattered electron detectors 822a and 822b generate many electron-hole pairs from a single low-energy back-scattered electron (such as an electron having an energy of about 2 keV or less). Conventional silicon detectors unavoidably have a thin oxide, such as a native oxide, coating on the surface of the silicon, which blocks most electrons with energies below about 2 keV from reaching the silicon, or alternatively have a thin metal (such as Al) coating on the surface which scatters and absorbs a significant fraction of incident low-energy electrons. In a preferred embodiment, solid-state electron detectors described herein have a pin-hole free pure boron coating on their surface. A pin-hole free pure boron coating prevents oxidation of the silicon and allows efficient detection of low energy electrons (including electrons with energies less than 1 keV). Methods for fabricating silicon detectors with pin-hole free pure boron coatings and the design of such detectors are described in U.S. Published Patent Application 2013/0264481 entitled “Back-illuminated Sensor With Boron Layer”, and filed by Chern et al. on Mar. 10, 2013. This patent application is incorporated herein by reference.

The bubble located in the lower-left portion of FIG. 8 illustrates a simplified solid-state sensor 823 utilized by one or more of electron detectors 821, 822a, and 822b to convert incident back-scattered or secondary electrons e_{INCIDENT} into measurable charges entirely within a single integral semiconductor (e.g., epitaxial silicon) structure 824. Sensor 823 includes a p-type electron-sensitive layer 827 configured to generate multiple electrons e₈₂₇ in response to each incident electron e_{INCIDENT} (or X-ray photon) that enters through a front-side surface 827-F, an n-type buried channel layer 825 configured to transfer electrons e₈₂₅, which represent at least some of generated electrons e₈₂₅, to an n+ floating diffusion FD, an amplifier 829 that generates an output signal OS according to a charge (voltage) V_{FD} collected on floating diffusion FD. Buried channel layer 825 is disposed on a top surface 827-B of the electron-sensitive layer 827 to facilitate efficient collection of electrons e₈₂₇ generated by electron-sensitive layer 827, and floating diffusion FD is disposed in buried channel layer 825 to facilitate receiving electrons e₈₂₅, whereby the measured charge (voltage) V_{FD} is made proportional to the number of electrons e_{FD} captured by floating diffusion FD. According to an aspect of the invention, p-type electron-sensitive layer 827, n-type buried channel layer 825, n+ floating diffusion FD and amplifier 829 are collectively fabricated by diffused dopants on integral semiconductor structure 824, whereby the entire incident-electron-to-readout conversion takes place entirely within semiconductor structure 824. An optional pure boron layer 828 is formed on bottom surface 827-F of electron-sensitive layer 827 such that incident electron C_{INCIDENT} passes through pure boron layer 828 before entering electron-sensitive layer 827. As discussed in additional detail below, in addition to sensor 823 each solid-state electron detector includes at least one analog-to-digital converter 826 that converts output signal OS to a digital form for transmission as digital image data signal IDx (i.e., signal ID1 in the case of back-scattered electron detectors 822a or 822b, or signal ID2 in the case of secondary electron detector 821) to computer 860.

The various circuits and systems of SEM 800 are described above in a simplified form for brevity, and it is understood that these circuit and systems include additional features and perform additional functions. For example, although back-scattered electron detectors 822a/822b and secondary electron detector 821 of SEM 800 are described above as including simplified sensor 823 to introduce certain key features of the present invention with brevity, it is understood that back-scattered electron detectors 822a/822b and secondary electron detector 821 are preferably implemented using the multi-pixel electron detectors described below. Moreover, in addition to generating images of scanned sample areas, computer 860 may be configured to perform additional functions, such as determining the presence of a defect and/or the type of the defect based on incident electron energy values indicated by the image data signals using the methods described below.

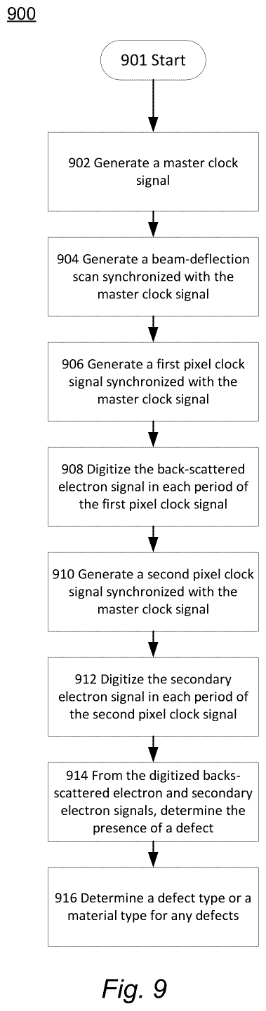

FIG. 9 illustrates an exemplary method 900 of inspecting or reviewing a sample such as a semiconductor wafer, reticle, or photomask. The method illustrated in FIG. 9 may be repeated for each area on the sample that is to be inspected or reviewed. In a review SEM, the areas to be reviewed may have previously been identified by an optical or SEM inspection as potentially containing a defect or particle.

For each area on the sample to be inspected or reviewed, the exemplary method 900 starts at step 901. A master clock signal is generated at step 902 that is used to control the timing of the scanning of the primary electron beam and the acquisition of image data.

A beam-deflection scanning pattern is generated at step 904. This beam-deflection scanning pattern generates voltages and/or currents that go to beam deflectors such as those shown at 805 and 809 in FIG. 8. The pattern may be a raster scan, a serpentine pattern, a square spiral, or other pattern that covers the area of the sample. A scanning pattern may also contain, for example, delays and dummy scans where no data is collected to control charge-up of the sample surface.

A first pixel clock signal is generated at step 906. The first pixel clock signal is synchronized with the master clock signal. The first pixel clock signal may be at the same frequency as the master clock signal, a frequency that is a multiple of the master clock signal, a frequency that is a sub-multiple of the master clock signal (i.e. the master clock signal frequency divided by an integer), or a frequency that is a rational multiple of the master clock signal frequency.

In step 908, on each period of the first pixel clock signal, signals collected in the back-scattered electron detector are read out and digitized.

In step 910, a second pixel clock signal is generated that is synchronized to the master clock signal. The second pixel clock signal may be at the same frequency as the master clock signal, a frequency that is a multiple of the master clock signal, a frequency that is a sub-multiple of the master clock signal (i.e. the master clock signal frequency divided by an integer), or a frequency that is a rational multiple of the master clock signal frequency. The second pixel clock signal may be at the same frequency as the first pixel clock signal. In one embodiment the first pixel clock signal is used for both the first and second pixel clock signals and no separate second pixel clock signals is generated.

In step 912, on each period of the second pixel clock signal (or the first pixel clock signal if no second pixel clock signal is used), signals collected in the secondary electron detector are read out and digitized.

In step 914, the digitized back-scattered and secondary electron signals are used to determine the presence of one or more defects in the scanned area. A defect may comprise the presence of material (such as a particle) that is not supposed to be there, the absence of material that is supposed to be there (such as may happen with an over-etched condition), or a malformed pattern.

In an optional step 916, for each defect found in step 914, the defect type or the material type of the defect may be determined. For example, high atomic number elements generally scatter a greater fraction of incident electrons than low atomic number elements. The back-scattered electron signal may be used to infer the presence or absence of a high-atomic number element (such as a metal). In step 916, when an area is being reviewed that has previously been inspected, the prior inspection data (optical and/or e-beam) may be used in combination with the digitized back-scattered and secondary electron signals in order to better determine the defect or material type. In one embodiment, steps 914 and 916 may be combined into a single step that simultaneously determines the presence and type of a defect.

Method 900 may be repeated from the beginning for each area on the sample to be reviewed or inspected.

FIG. 10A illustrates an exemplary simplified multi-pixel electron detector 1000 for use in a review SEM or other SEM system, such as SEM 800 shown in FIG. 8. Electron detector 1000 generally includes a sensor circuit 1010 and a signal processing circuit 1020. In the preferred embodiment illustrated in FIG. 10A, sensor circuit 1010 is fabricated on a silicon structure (chip) 1011, and signal processing circuit 1020 is fabricated on a separate silicon structure (chip) 1021 for reasons that will become clear below. In an alternative embodiment (not shown), both sensor and signal processing circuits are fabricated on the same silicon chip.

Referring to the lower portion of FIG. 10A, sensor 1010 includes sixteen pixels 1015-11 to 1015-44 disposed in a four-row, four-column (4×4) array. For descriptive purposes, “rows” of pixels are aligned in the arbitrarily assigned X-axis direction in FIG. 10A, whereby pixels 1015-11 to 1015-14 form a first row, pixels 1015-21 to 1015-24 form a second row, pixels 1015-31 to 1015-34 form a third row, and pixels 1015-41 to 1015-44 form a fourth row. Similarly, “columns” of pixels are aligned in the Y-axis direction shown in FIG. 10A, whereby pixels 1015-11 to 1015-41 form a first column, pixels 1015-12 to 1015-42 form a second column, pixels 1015-13 to 1015-43 form a third column, and pixels 1015-14 to 1015-44 form a fourth column. In practical applications, sensor circuits are expected to include arrays of 16×16, 32×32, 64×64 or more pixels, where the pixels of these larger arrays include features similar to those of the simplified 4×4 array described below. Moreover, the numbers of pixels in each row/column of the array need not be powers of two, nor do the number of pixels in each row need to be equal to the number of pixels in each column. In one embodiment (e.g., in the case of back-scattered electron detectors 822a or 822b, shown in FIG. 8), sensor 1010 includes a hole (not shown) in the middle of the sensor to allow the primary electron beam to pass through the sensor. Although pixels 1015-11 to 1015-44 are depicted as having square shapes, the pixels may also be rectangular or hexagonal.

According to an aspect of the invention, each pixel of sensor circuit 1010 includes electron-sensitive, buried channel, floating diffusion and amplifier circuit structures similar to those described above with reference to FIG. 8. By way of example, referring to pixel 1015-41 in FIG. 10A, each pixel generally includes a p-type electron-sensitive region 1012A, an n-type buried channel layer 1016, a floating diffusion FD, and an amplifier 1017. P-type electron-sensitive region 1012A is formed by the portion of epi layer 1012 located below pixel 1015-41, and functions in the manner described above with reference to FIG. 8 to generate multiple electrons in response to incident electrons. Buried channel layer 1016 is formed by an n-type dopant diffused into epi layer 1012 over electron-sensitive region 1012A, and functions to transmit electrons generated by electron-sensitive region 1012A to floating diffusion FD. Floating diffusion FD, which is illustrated using a schematic capacitor symbol for descriptive purposes, is formed by an n+ dopant diffused into buried channel layer 1016, and functions to collect at least some of the multiple electrons generated by electron-sensitive region 1012A, thereby generating a corresponding charge (voltage) in the manner described above with reference to FIG. 8. Amplifier 1017 includes transistors M1, M2 and M3, and functions to generate associated output signal OS41 whose voltage level is determined by a number of electrons collected on floating diffusion FD at any given readout operation. Each pixel also includes a reset transistor RT that functions to reset the voltage level of pixel floating diffusion FD after each readout operation.

Sensor circuit 1010 is depicted in FIG. 10A in a cut-away fashion to illustrate a preferred embodiment in which pixels 1015-11 to 1015-44 are fabricated on a membrane structure including epitaxial (epi) layer 1012 and a boron layer 1013. In one embodiment, substrate 1011 is a p+ (i.e. highly p doped) substrate, and epi layer 1012 is a p− epi layer (i.e. a layer with a low concentration of p dopant). Preferably a thickness T of epi layer 1012 is between about 40 micrometers (μm) and 100 μm in order to keep the time taken for electrons to drift from the electron-sensitive region to the buried channel layer limited to less than about 10 ns, while providing good mechanical strength. Depending on the mechanical support provided by substrate 1011, epi layer 1012 may be made thinner than 40 μm, such as between about 10 μm and 40 μm. After epi layer 1012 is formed, one or more additional layers (not shown) are formed over epi layer 1012 (e.g., a gate oxide layer, a silicon nitride gate layer, and one or more dielectric layers), and one or more doped regions are formed in epi layer 1012 (e.g., n-type buried channel portions 1016, n+ floating diffusion FD, channel regions associated with a reset transistor RT and an amplifier 1017, along with doped regions associated with front-side circuit elements (not shown) forming control circuit 1018, which is disposed in peripheral regions of the pixel array). Forming the various pixel transistors and front-side circuit elements includes implanting or doping portions of the front side of the epi layer, and may involve patterning the gate layer. The portion of substrate 1011 disposed below pixels 1015-11 to 1015-44 is then removed (thinned) to expose electron sensitive (front-side) surface 1012-ES, and then boron layer 1013 is formed on electron sensitive surface 1012-ES. Additional detail related to the formation of the membrane structure depicted in FIG. 10A is provided, for example, in co-owned and co-pending U.S. Published Patent application 2013/0264481 entitled “Back-illuminated Sensor With Boron Layer”, and filed by Chern et al. on Mar. 10, 2013, which is incorporated herein by reference in its entirety.

FIG. 10B is a simplified diagram showing an exemplary pixel 1015-41 of FIG. 10A in additional detail. Specifically, amplifier 1017 includes a first NMOS transistor M1 having a drain terminal connected to a voltage source VOD, and a gate terminal connected to and controlled by the charge stored on floating diffusion FD, and a source terminal connected to the drain terminal of a second NMOS transistor M2 and the gate terminal of a third NMOS transistor M3. The gate and source terminals of transistor M2 are connected to ground, and the drain terminal of transistor M3 is connected to voltage source VOD, whereby the output terminal of amplifier 1017 is formed by the source terminal of transistor M3. Pixel 1015-41 also includes an NMOS reset transistor RT having a source terminal connected to floating diffusion FD, a gate terminal controlled by a reset control signal RG, and a drain terminal connected to a reset voltage RD. During operation of pixel 1015-41, each detection/readout cycle begins by resetting floating diffusion FD to voltage RD by way of toggling reset transistor RT, then waiting a predetermined detection period, then sampling output signal OS41. If zero incident (i.e., back-scattered or secondary) electrons enter the electron-sensitive region of pixel 1015-41 during the detection period, the voltage levels on floating diffusion FD and output signal OS41 do not change significantly from the reset values at readout. If one or more incident (i.e., back-scattered or secondary) electrons enter the electron-sensitive region of pixel 1015-41 during the detection period, the voltage level on floating diffusion FD changes (becomes more negative) by an amount proportional to the number and energy of the incident electron (which is indicated by the number of electrons accumulated in floating diffusion FD), whereby the voltage level of output signal OS41 at readout provides the approximate energy level of the incident electron detected during that detection/readout cycle (or sum of energies if multiple electrons are incident during that detection/readout cycle). When operated at a 100 MHz operating speed, 100 million detection/readout cycles are performed each second on each pixel.

According to a preferred embodiment of the present invention depicted in FIG. 10B, the floating diffusion of each pixel is located in a central region of its pixel, and the nominal lateral size dimensions of each pixel is approximately 250 μm or less to facilitate the transfer of electrons to the floating diffusion during each detection/readout cycle. Referring briefly to FIG. 10A, lateral size dimensions are measured in the X-Y plane horizontal to silicon structure 1011, and represent the area occupied by each pixel. Referring to FIG. 10B, floating diffusion FD is located in a central region C (FIG. 11A) of the area occupied by pixel 1015-41, where the width of pixel 1015-41 is indicated by width dimension X1, and the length of pixel 1015-41 is indicated by dimension Y1.

According to the presently preferred embodiment, both dimensions X1 and Y1 are approximately 250 μm or less to facilitate high speed readout operations. Because of the drift velocity of electrons in silicon, when readout of pixel 1015-41 at a data rate of about 100 MHz or higher is desired, it is preferable that the lateral dimensions of each pixel do not exceed about 250 μm so that electrons can be driven to the centrally located floating diffusion FD in about 10 nanoseconds (ns) or less. For lower speed operation, pixels larger than 250 μm may be acceptable. For operation at speeds much higher than 100 MHz, pixel dimensions smaller than 250 μm are preferred.

Referring to the upper portion of FIG. 10A, analog-to-digital converters 1025-11 to 1025-44 are fabricated on semiconductor substrate 1021 along with optional signal processing circuitry 1028-1 and optional signal transmission circuitry 1028-2 according to known techniques. In one embodiment, to facilitate the one-to-one signal connection between pixels 1015-11 to 1015-44 and analog-to-digital converters 1025-11 to 1025-44 discussed below, analog-to-digital converters 1025-11 to 1025-44 are arranged in a pattern that generally mirrors the array pattern (matrix) formed by pixels 1015-11 to 1015-44. Digital values generated by analog-to-digital converters 1025-11 to 1025-44 are transmitted by conductors 1029 to processing circuitry 1028-1 configured, for example, to calculate the approximate energy of an incident electron based on the digitized output signal (image data) received from an associated pixel of the sensor circuit. Optional high speed data transmission circuitry 1028-2 is utilized, for example, to transmit image data signal ID to an external processing system (e.g., a computer).

In one embodiment, in addition to the array of analog-to-digital converters 1025-11 to 1025-44 the signal processing circuit 1020 includes processing circuitry 1028-1 configured, for example, to calculate the approximate energy of an incident electron based on the digitized output signal (image data) received from an associated pixel of the sensor circuit. In another embodiment, the signal processing circuit 1020 also includes high speed data transmission circuitry 1028-2 for transmitting an image data signal ID to an external processing system (e.g., a computer).

Referring again to the lower portion of FIG. 10A, each output signal OS11 to OS44 respectively generated by pixels 1015-11 to 1015-44 is transmitted by way of an associated conductive path (indicated by dotted lines) to an associated analog-to-digital converter 1025-11 to 1025-44 disposed on signal processing circuit 1020. For example, pixel 1015-11 transmits output signal OS11 by way of a dedicated conductive path to analog-to-digital converter 1025-11, pixel 1015-12 transmits output signal OS12 directly to analog-to-digital converter 1025-12, etc. In the preferred embodiment described below with reference to FIG. 10C, output signals OS11 to OS44 may be transmitted by way of metal pads, solder balls/bumps, or similar structures that provide individual signal paths between each pixel and its associated analog-to-digital converter.

As explained herein, each pixel has multiple signals or electrical connections, such as gates, control signals, power supply, and ground. The interconnect density would be too high for practical and cost-effective assembly to individually connect each of these signals to each pixel. Preferably most, or all, of these signals are connected together between neighboring pixels and brought to a convenient location, such as near the edge of the sensor where an external electrical connection can be made. For example, as indicated in FIG. 10A, signals RD, RG and VOD are transmitted from a control circuit area 1018 to the pixels in each row by way of metal conductors (signal lines) 1019. In a practical device, there may be more than three signals connected together between pixels, but three signals are shown here to illustrate the principles. The external connections to signals such as RD, RG and VOD may be made with bond wires, solder balls or bumps (as described below with reference to FIG. 10C) or other techniques. As shown in FIG. 10A, the connection between the signals may be predominantly, or exclusively, made in one direction, such as the horizontal direction shown, in order to simplify the interconnections and allow the use of only a single layer of metal. With, for example, a large enough area outside the active area of the sensor, or with two or more layers of metal, interconnections may easily be made in two dimensions, if the extra cost can be justified.

In contrast to the shared signal lines of sensor circuit 1010, as indicated at the upper portion of FIG. 10A, each analog-to-digital converter 1025-11 to 1025-44 of signal processing circuit 1020 is coupled to processing circuit 1028-1 by way of an individual conductor (signal line) 1029 in order to maximize data transfer and processing.

FIG. 10C illustrates exemplary electron detector 1000A comprising electron sensor 1010A, an ASIC (signal processing circuit) 1020A and a substrate 1001. Substrate 1001 provides mechanical support for the electron detector 1000A and allows external electrical connections (not shown) to the electron detector 1000A. Substrate 1001 may comprise silicon or a ceramic material. Electron sensor 1010A and ASIC 1020A are fabricated on separate silicon substrates (dies or chips) that are then stacked on top of one another, as shown. Alternatively, electron sensor 1010A and ASIC 1020A may be placed on opposite sides of substrate 1001, or side-by-side on the substrate 1001 (not shown). Electron sensor 1010A is preferably a multi-pixel electron sensor similar to that illustrated in FIGS. 10A and 10B, and even more preferably includes pixels such as those described below, for example, with reference to FIGS. 11A and 11B. During operation, electron detector 1000A is positioned such that electron sensitive surface 1012-ES faces a sample or other electron source, whereby detected electrons are incident on electron sensitive surface 1012-ES and are detected as described herein.

Electron sensor 1010A is electrically connected to ASIC 1020A by solder balls or bumps 1006. In a preferred embodiment, the output signal generated by each pixel 1015 of electron sensor 1010A is transmitted by way of an associated solder ball/bump 1006 to an associated analog-to-digital converter 1025 of ASIC 1020A. For example, output signal OS11 generated by pixel 1015-11 is transmitted by way of an associated conductor to a first pad 1009 disposed on the lower surface of sensor 1010A, and from first pad 1009 by way of associated solder ball/bump 1006-11 to a second pad disposed on ASIC 1020A, from which output signal OS11 is transmitted to the input terminal of associated analog-to-digital converter 1025-11. One or more solder balls/bumps 1006 may also be used to transmit signals from ASIC 1020A (e.g., from circuit 1028) to control circuit 1018 of sensor 1010A. These balls or bumps also provide mechanical support for electron sensor 1010A and provide thermal conductivity to electron sensor 1010A. Solder balls or bumps may instead be used to directly mount electron sensor 1010A to substrate 1001 (not shown). Metal pads may also be provided on electron sensor 1010A to enable wire bonds to provide electrical connections to electron sensor 1010A, for example to surface 1012-ES of electron sensor 1010A.

ASIC 1020A may be mounted directly to substrate 1001 as shown, or may be mounted and electrically connected to substrate 1001 by solder balls or bumps (not shown). If ASIC 1020A includes through-silicon vias, then solder balls or bumps may be used on both sides of ASIC 1020A. Metal pads 1007 and 1027 and/or wire bonds 1039 may be used to make electrical connections between ASIC 1020A and substrate 1001. Similar wire bond connections may be made between sensor 1010A and substrate 1001, or all connections between substrate 1001 and sensor 1010A may be made through ASIC 1020A. ASIC 1020A may comprise a single ASIC or two or more ASICs. For example, in one embodiment, ASIC 1020A may comprise two ASICs, one ASIC containing primarily analog functions and the other ASIC containing primarily digital functions. Additional integrated circuits, such as a fiber-optic transmitter or a fiber-optic receiver (not shown) may also be mounted on substrate 1001.

ASIC 1020A preferably includes analog-to-digital converters 1025 configured to digitize output signals from pixels 1015 of electron sensor 1010A. In one embodiment. ASIC 1020A includes one analog-to-digital converter 1025 for each pixel 1015 so that all pixels 1015 can be digitized in parallel at high speed, such as at a speed of 100 MHz or higher. With a high digitization rate, such as 100 MHz or higher, each pixel 1015 may detect, at most, a few electrons per clock period, so each analog-to-digital converter 1025 may only need 8, 6 or fewer bits. It is easier to design a converter with a smaller number of bits to operate at high speed. An analog-to-digital converter with a small number of bits may occupy a small area of silicon making it practical to have a large number, such as 1024 or more on one ASIC.

ASIC 1020A preferably implements part of the method shown in FIG. 9. For example, when the electron detector 1000A is used as a back-scattered electron detector, ASIC 1020A may implement step 908, or when the electron detector is used as a secondary electron detector, ASIC 1020A may implement step 912. ASIC 1020A may further incorporate circuits to generate the first pixel clock signal or the second pixel clock signal described in FIG. 9, or may receive a pixel clock signal from an external circuit.

When the electron detector 1000A is used as a secondary electron detector, ASIC 1020A may implement a de-scanning of secondary electrons similar in result to that implemented by electron optics in the '791 patent cited above. ASIC 1020A may sum signals from a group of pixels corresponding to secondary electrons emitted from the sample into one range of angles and output that sum as one signal. As the beam deflection changes. ASIC 1020A may sum a different group of pixels under the changed deflection that corresponds to approximately the same range of angles. Since the same master clock is used to generate or synchronize the beam deflection and to generate or synchronize the first and second pixel clocks, the ASIC 1020A has the necessary timing information to adjust which groups of pixels are summed together in synchrony with the beam-deflection scan.

When the electron current is low and the pixel clock rate is high enough such that the average number of electrons per pixel is much less than one, then the charge collected in a single pixel in a single period of the pixel clock period can be used to determine whether an electron was detected in that pixel in that clock period, and, if detected, to determine an approximate energy of that electron. The boron coating on the electron sensor surface is necessary to enable this capability. Without a boron coating, few, or no, electrons are created per incident electron when the incident electron energy is less than about 1 keV. With an approximately 5-nm thick boron coating, about 100 electrons are created per incident 1 keV electron. Such a signal can be detected above the noise level if the floating diffusion capacitance is small enough to generate more than about 10 microvolts (μV) per electron. In one embodiment, the floating diffusion capacitance is small enough that the floating diffusion generates more than about 20 μV per electron. For such low level signals, coupling each pixel by as short a path as possible to the corresponding analog to digital converter is important for keeping the noise level low and the stray capacitances low. Attaching the electron sensor directly to the ASIC allows for a very short path from each pixel to the corresponding analog-to-digital converter.

When individual electrons can be detected, ASIC 1020A may use the signal level to determine an approximate energy of that electron. ASIC 1020A may further threshold, count or bin incident electrons according to their energies in order to detect or classify one or more types of defect or material on the sample.

FIGS. 11A and 11B are exploded and assembled perspective views, respectively, showing a simplified pixel 1100 of an electron sensor (e.g., sensor 1010 described above with reference to FIG. 10A) according to another exemplary specific embodiment of the present invention. Similar to the pixels described above, pixel 1100 preferably has a size (nominal lateral dimension) of between approximately 200 μm and 250 μm.

Referring to FIG. 11A, similar to the pixel features mentioned above, pixel 1100 includes a p-type electron-sensitive layer 1157A, an n-type buried channel layer 1155 disposed over the p-type electron-sensitive layer 1157A, an n+ floating diffusion FD formed in n-type buried channel layer 1155, an amplifier 1110, and an optional pure boron layer 1160 disposed below the p-type electron-sensitive layer 1157A.

Buried channel layer 1155 and electron-sensitive layer 1157A are disposed in an epitaxial silicon layer 1157 such that an upper extent of buried channel layer 1155 coincides with (forms) a top (first) surface 1157-S1 of epitaxial silicon layer 1157, and electron-sensitive layer 1157A comprises a portion of epitaxial silicon layer 1157 disposed between buried channel layer 1155 and a bottom (electron-sensitive) surface 1157-S2 of epitaxial silicon layer 1157. Epitaxial silicon layer 1157 has a thickness preferably between about 10 μm and 100 μm, and is lightly p-doped such that the resistivity is, in one embodiment, between about 10 and 2000 Ωcm. A thicker epi layer provides more mechanical strength, but may generate more dark current. A lower doping level (higher resistivity) may be required for a layer thicker than about 20 μm or 30 μm in order to maintain a fully depleted state in the bulk of the silicon. Too low a doping level is not preferred as that will lead to a higher dark current.

Buried channel layer 1155 is created under top surface 1157-S1 of epitaxial silicon layer 1157 by n-type doping diffused using known techniques. The doping concentration of buried channel layer 1155 must be orders of magnitude greater than the doping concentration in epitaxial silicon layer 1157, so that epitaxial silicon layer 1157 is fully depleted during operation. In one preferred embodiment, the concentration of n-type dopants in the buried channel layer 1155 is between about 10¹⁶ and 5×10¹⁶ cm⁻³.

Floating diffusion FD comprises a relatively small n+ doped region disposed in buried channel layer 1155 that is configured to collect electrons generated in pixel 1100 in response to incident back-scattered or secondary electrons. In one preferred embodiment, floating diffusion FD has a nominal lateral size between about 1 and 5 μm, and the concentration of n-type dopants in floating diffusion FD is between about 10¹⁹ and 10²¹ cm⁻³. A connection for transmitting stored charges to amplifier 1110 is made to floating diffusion FD using known techniques.

Pure boron layer 1160 is preferably deposited on the back or bottom surface 1157-S2 of epitaxial silicon layer 1157. Boron layer 1160 is preferably between about 2 nm and 10 nm thick, such as a thickness of about 5 nm. As explained in U.S. Published Patent Application 2013/0264481 entitled “Back-illuminated Sensor With Boron Layer”, and filed by Chern et al. on Mar. 10, 2013, incorporated by reference above, during the boron deposition process, some boron diffuses a few om into the epitaxial silicon layer 1157 to form a thin, very highly doped p+ layer adjacent to the pure boron layer 1160. This p+ layer is important for optimal operation of the sensor. This p+ layer creates an electric field that drives electrons towards the buried channel 1155, reduces dark current from the back surface of the epitaxial silicon layer 1157, and increases the conductivity of the silicon surface allowing the sensor to function at high incident electron currents as well as low currents. In one embodiment, during deposition of the pure boron layer 1160, additional boron is allowed to diffuse into the silicon. This can be done by one of several methods. In one exemplary method, a thicker layer of boron is deposited than the final desired thickness (for example an 6 nm to 8 nm layer may be deposited when a 5 nm final thickness is required) and then the boron is allowed to diffuse into silicon epitaxial layer 1157 by keeping the sensor at the deposition temperature or a higher temperature (such as between about 800° C. and 950° C.) for a few minutes. In another exemplary embodiment, a few nm thick layer of boron may be deposited on the silicon, then the boron may be driven in at the deposition temperature or a higher temperature, and then the final desired thickness of boron (such as 5 nm) may be deposited.

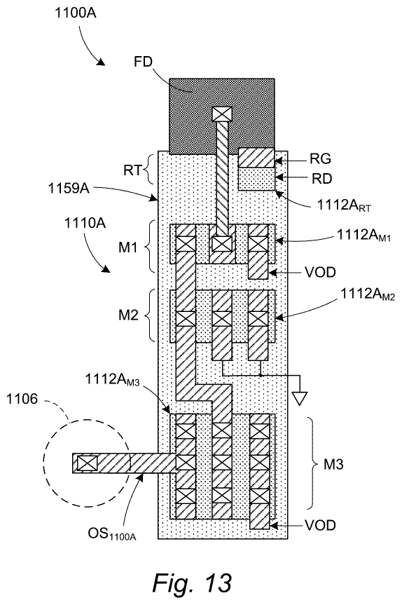

According to an aspect of the present embodiment, amplifier 1110 is formed in and over an elongated p-well region 1159 that extends vertically from top surface 1157-S1 into electron-sensitive layer 1157A, and extends outward from a point adjacent to the pixel's central region C (i.e., toward peripheral outer edge 1155-OPE of n-type buried channel layer 1155). Note that p-well region 1159 is shown separated from silicon epitaxial layer 1157 in FIG. 11A for descriptive purposes, but in fact comprises a p-type doped region of silicon epitaxial layer 1157. In alternative embodiments, p-well 1159 is either entirely contained within the square-shaped peripheral boundary of pixel 1100, or extends past the peripheral boundary (e.g., into an adjacent pixel). In one embodiment, p-well 1159 is formed by implanting boron with a concentration substantially higher than the dopant concentration in silicon epitaxial layer 1157, and then n-type channel regions 1112 of the various transistors of amplifier 1110 are formed in p-well 1159, whereby p-well 1159 serves to prevent electrons from migrating directly from the epitaxial silicon layer into channel regions 1112. In one embodiment, the p-well extends under the floating diffusion and the channel region of the pixel's reset transistor (discussed below with reference to FIG. 13) to prevent electrons from migrating directly from the epitaxial silicon layer into the floating diffusion.

As indicated in FIG. 11A, one or more dielectric layers 1154 overlay the buried channel. Dielectric layers 1154 may comprise a single silicon dioxide layer or a silicon nitride layer on top of a silicon dioxide layer or a silicon oxide layer on top of a silicon nitride layer on top of a silicon dioxide layer. Individual layer thicknesses may be between about 20 nm and 50 nm.

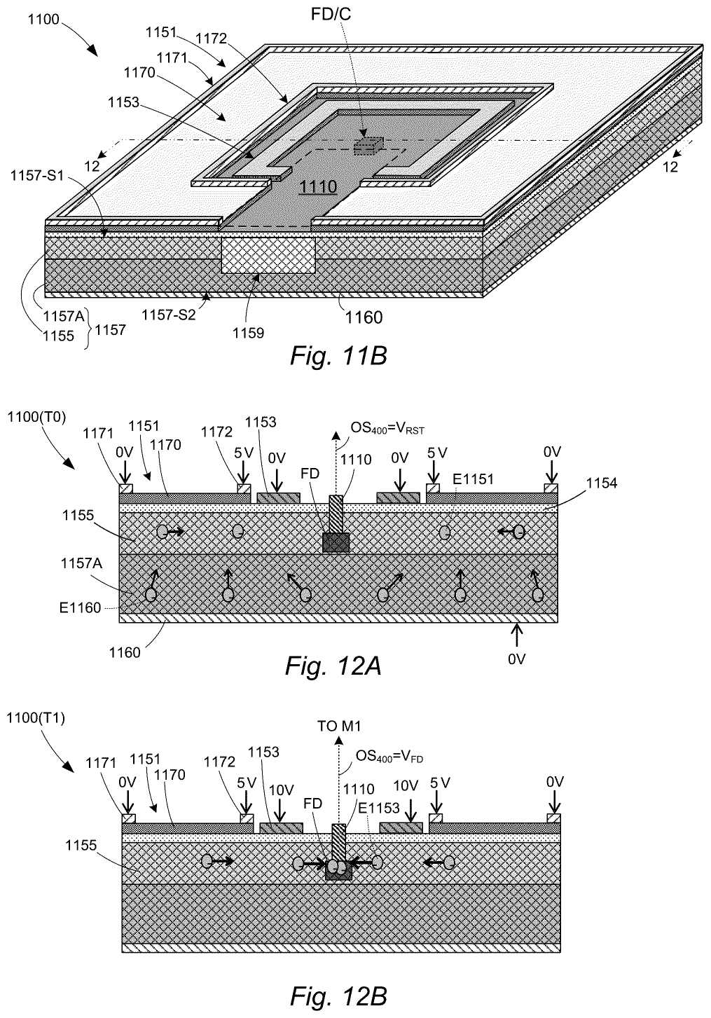

According to another aspect, pixel 1100 further includes a resistive gate 1151 comprising one or more polycrystalline or amorphous silicon gate structures 1170 disposed on dielectric layer(s) 1154 and configured to cover most of upper surface 1157-S1. As indicated in FIG. 11A, resistive gate 1151 includes an outer peripheral edge 1151-OPE that substantially aligns with the periphery of pixel 1100 (i.e., generally aligns with outer peripheral edge 1155-OPE of buried channel layer 1155), and defines a central opening 1151-CO such that an inner peripheral edge 1151-IPE of resistive gate 1151 (i.e., the inner edge of gate structure 1170) substantially surrounds and is spaced laterally from central pixel region C (e.g., as indicated in FIG. 11B). In one embodiment gate structure 1170 comprises polycrystalline silicon having a relatively light doping level (e.g., having a resistivity greater than about 30Ω per cm) such that, when a decreasing potential difference is applied between inner peripheral edge 1151-IPE and outer peripheral edge 1151-OPE, resistive gate 1151 generates an associated electric field that biases electrons in buried channel layer 1155 toward the pixel's central region C in the manner described below with reference to FIGS. 12A and 12B. To facilitate operating resistive gate 1151 such that electrons from all peripheral lateral areas of pixel 1100 are biased toward central region C for collection by floating diffusion FD, resistive gate 1151 also includes elongated conductors (e.g., metal wires) 1171 and 1172 disposed on gate structure 1170 along and adjacent to outer peripheral edge 1151-OPE and inner peripheral edge 1151-IPE, respectively. As described below, a negative potential relative to elongated conductor 1172 is applied to elongated conductor 1171, such as a voltage of −5 V. The resulting potential difference between conductors 1171 and 1172 generates a decreasing potential in a substantially radial direction in gate structure 1170 (i.e., between inner peripheral edge 1151-IPE and outer peripheral edge 1151-OPE) that drives electrons in the buried channel (see FIG. 11B) towards the floating diffusion FD. Additional connections to gate structure 1170 may be provided between conductors 1171 and 1172 and held at potentials intermediate to those applied to conductors 1171 and 1172 so as to modify the potential gradient in resistive gate 1151. Additional detail regarding the composition of resistive gate 1151 can be found in U.S. patent application Ser. No. 11/805,907 entitled “Inspection System Using BackSide Illuminated Linear Sensor” and filed by Armstrong et al. on May 25, 2007 (published as U.S. Patent Application Publication 2011/0073982 by Armstrong et al. on Mar. 31, 2011). This patent application is incorporated by reference herein in its entirety.

According to another aspect, pixel 1100 further includes one or more optional additional gate structures disposed between resistive gate 1151 and floating diffusion FD to further drive electrons onto floating diffusion FD, or to control when the electrons are collected/accumulated on floating diffusion FD. For example, pixel 1100 includes a C-shaped highly-doped polycrystalline gate structure 1153 disposed on dielectric layers 1154 and inside inner peripheral edge 1151-IPE of resistive gate 1151. Constant or switched voltages may be applied to gate structure 1153 to control and ensure efficient charge transfer from the portions of buried channel layer 1155 under resistive gate 1151 to floating diffusion FD. In one embodiment described below with reference to FIGS. 12A and 12B, gate structure 1153 is utilized as a summing gate to which a low voltage, such as 0V (relative to bottom surface 1157-S2 or boron layer 1160), is applied during reset, and a high voltage, such as 10V, is applied during readout. In addition to summing gate 1153, one or more additional gates, such as a buffer gate, a transfer gate, and an output gate may be formed by associated additional gate structures placed between resistive gate 1151 and floating diffusion FD. Such gates are well known in CCD technology and may be operated in a similar manner in this electron sensor. See, for example, J. R. Janesick, “Scientific Charge-Coupled Devices”, SPIE Press, 2001, pp 156-165.

FIG. 11B shows simplified pixel 1100 in a partially assembled state. As indicated, most of pixel 1100 (i.e., most of top surface 1157-S1) is covered by amorphous silicon or poly-silicon gate structure 1170, which forms resistive gate 1151. The exposed region (indicated by dashed-line box) above p-well region 1159 is indicated for illustrative purposes as being empty, but in fact includes various connection structures and gates associated with the transistors forming amplifier 1110 and a reset transistor RT. An exemplary layout of these structures and gates is provided below with reference to FIG. 13. In one embodiment (not shown), summing gate 1153 overlaps (i.e., extends over and is separated by a suitable insulator to keep them electrically isolated) inner peripheral edge 1151-IPE (see FIG. 11A) of resistive gate 1151. This overlapped arrangement prevents fringe electric fields in the silicon under the gap between the two gate structures. These fringe fields can trap electrons in the buried channel or cause them to move in unexpected directions.

FIGS. 12A and 12B are simplified cross-sectional views showing pixel 1100 during an exemplary detection/readout cycle (operation), where FIG. 12A depicts pixel 1100 at a time TO during or immediately after floating diffusion FD is reset to a reset voltage (i.e., OS400 is equal to a reset voltage level VRST), and FIG. 12B depicts pixel 1100 at a subsequent time T1 when output signal OS400 is read out in the manner described above (i.e., when OS400 is equal to a voltage level V_{FD} determined by the number of electrons accumulated on floating diffusion FD between times T0 and T1). Note that the individual layers shown in FIGS. 12A and 12B are not drawn to scale, but are exaggerated in order to show them more clearly.

Referring to FIG. 12A, the back surface coated by pure boron layer 1160 is preferably held at a similar potential to the outer edge of the resistive gate (such as 0 V in the example). Since boron is conductive and since the silicon immediately under pure boron layer 1160 is highly doped with boron, the back surface may be sufficiently conductive that connecting to it at one, or a few, locations provides a sufficiently low impedance path for operation of the sensor at high incident currents, such as a current of about 10 to 50 nanoamperes (nA). The electric fields formed by these potential differences drive electrons (such as E1160) created in the epitaxial silicon (electron sensitive) region 1157A by back-scattered or secondary electrons incident on the sensor through pure boron layer 1160 towards buried channel 1155 as illustrated by the arrows on the electrons. A potential difference is applied to resistive gate 1151 between the outer edge of pixel 1100 and the inner edge of gate structure 1170 by way of conductors 1171 and 1172. In one example, 0V is applied to the outer edge by way of conductor 1171, and 5V is applied to the inner edge by way of conductor 1172, as shown. The resulting potential difference in gate structure 1170 produces an electric field that drives electrons (such as E1151) disposed in buried channel 1155 toward the center of pixel 1100 (i.e., causes these electrons to move toward floating diffusion FD).

In the example depicted in FIGS. 12A and 12B, summing gate 1153 is used to control and drive the electrons into floating diffusion FD. For example, as indicated in FIG. 12A, when transfer of electrons to floating diffusion FD is to be blocked (e.g., during reset), the voltage applied to summing gate 1153 is significantly lower than that applied to conductor 1172, whereby the electric field prevents electrons from readily flowing to floating diffusion FD and causes them to accumulate in buried channel 1155 underneath 1172 (as indicated by electron E1151). Conversely, as indicated in FIG. 12B, when electrons are to be transferred to floating diffusion FD (e.g., right before readout), summing gate 1153 receives a relatively high positive potential (relative to the voltage applied to conductor 1172, e.g., 10V relative to 5V applied to conductor 1172, as shown), causing electrons, such as E1153, underneath conductor 1172 to move toward floating diffusion FD. Since floating diffusion FD acts as a capacitor, the voltage V_{FD} on the floating diffusion FD at readout becomes more negative as more charge (electrons) accumulates. For small signals, the change in voltage V_{FD} is proportional to the accumulated charge (i.e. the capacitance of the floating diffusion FD is substantially constant), but as the amount of charge increases, the capacitance changes and the voltage increase is no longer linear. Although operation in the linear regime is usually preferred, in one embodiment, operation in a non-linear regime may be used to compress a high dynamic range signal. Since the sensitivity (charge-to-voltage conversion ratio) and speed depend on the capacitance of floating diffusion FD being small, it is generally preferable to keep floating diffusion FD as small as practical and minimize the size (and hence capacitance) of the structures connected to floating diffusion FD, including the channel of the reset transistor and the connection to the gate of transistor M1. By implementing FD as a VCVFD, depending on the system operating mode and the expected signal levels, an appropriate floating diffusion capacitance can be selected by a control voltage applied to the VCVFD as described above. In this way, the VCVFD can be used as a way to handle both small signals (smallest capacitance) and large signals (higher capacitance depending on the tuning of the VCVFD gate) to enable high dynamic range.

Note that the voltage values cited in the example above are merely examples. Different values may be used, and optimal values depend on many factors including the desired speed of operation of the sensor, the geometries of the one or more gates, the doping profiles and the thicknesses of the dielectric layer(s) 1154. Note also that it is typically convenient to define the backside (i.e., electron sensitive side) of a sensor as 0V (note that this voltage may be far from ground potential if the electron detector is floated at some potential other than ground), and conductor 1171 will preferably be connected to a similar potential.

In an alternative embodiment, instead of switching the reset transistor and the voltages on the various gates of each pixel, the reset transistor and the various gates are held at fixed potentials so that electrons generated in the epitaxial silicon (electron sensitive) region 1157A can flow continuously to the floating diffusion FD. In this mode, the voltage on the reset gate RG (FIG. 10B) must be held at a voltage that causes the reset transistor RT to be in a high resistance, partially conductive, state (such as a channel resistance between about 500 kΩ and a few MΩ) rather than “off” (which corresponds to a channel resistance of hundreds of MΩ or higher) or “on” (which corresponds to a channel resistance of a few kΩ or lower).

In this embodiment, the gate or gates between the inner peripheral edge of resistive gate 1170 and the floating diffusion FD must each be held at successively higher voltages, all higher than that of conductor 1172, so that electrons in the buried channel 1155 will be driven towards floating diffusion FD. For example, if conductor 1172 is at a potential of 5V, then summing gate 1153 could be held at a voltage of 6V. If there were another gate (not shown) between the inner peripheral edge of resistive gate 1170 and the summing gate 1153, then that other gate could, for example, be held at 6V and the summing gate 1153 at 7V. The reset drain RD (FIG. 10B) must be held at a voltage significantly more positive than the inner-most gate (such as summing gate 1153) so as to keep the floating diffusion FD at a sufficiently high potential relative to all the gates to attract the electrons in the buried channel. For example the reset drain RD might be held at 15V.

As will be readily understood, the channel of the reset transistor RT and the capacitance of the floating diffusion FD form an RC time constant that determines how quickly a voltage on the floating diffusion FD decays back to the reset drain RD voltage after electrons arrive at floating diffusion FD. For example, if the analog-to-digital converters are sampling each pixel at 100 MHz (i.e., once every 10 ns), then an RC time constant of approximately 20 ns or 30 ns might be appropriate. In this example, if the capacitance of the floating diffusion is about 10 fF, then the reset gate RG voltage should be set so that the resistance of the channel of the reset transistor RT is about 2.5 MΩ so as to give a time constant of about 25 ns.

This embodiment is made possible by the sensor disclosed herein because each pixel is connected to its own analog to digital converter. In a conventional two-dimensional CCD or CMOS image sensor, charges need to be stored and read out serially as the number of analog to digital converters is fewer than the number of pixels. Furthermore, conventional CMOS image sensors use transistors and gates with surface channels rather than buried channels. Surface channels, in contrast to buried channels, generate noise and cannot transfer small charges without loss.

FIG. 13 is a simplified plan view showing a partial pixel 1100A, and in particular shows an exemplary layout including a floating diffusion FD, an amplifier 1110A and a reset transistor RT utilized by pixel 1100A according to an exemplary specific embodiment of the present invention. In one embodiment, pixel 1100A is substantially identical to pixel 1100 described above (i.e., where floating diffusion FD is located in a central region of pixel 1100A), so the non-illustrated portions of pixel 1100A are omitted for brevity. In FIG. 13, doped regions (e.g., floating diffusion FD) are indicated by dot-type shaded regions, conductive structures (e.g., polysilicon or metal) are indicated by slanted-line regions, and vertical metal vias are indicated by boxes including “X” symbols. Note that the various amplifier polysilicon or metal structures are separated (i.e., not contiguous), and are patterned and interconnected using standard techniques. In this example, reset transistor RT is disposed directly below floating diffusion FD, and amplifier 1110A includes transistors M1, M2 and M3 that are connected and function in a manner similar to that described above with reference to FIG. 10B. Additional connections and vias associated with the structures shown in FIG. 13 are omitted for clarity.

Referring to the upper portion of FIG. 13, floating diffusion FD is disposed adjacent to p-well region 1159A, which is formed in the manner described above and includes various n-type channel regions associated with reset transistor RT and transistors M1 to M3 of amplifier 1110A. For example, reset transistor RT includes an n-type channel region 1112A_{RT} that is disposed in p-well region 1159A immediately below and connected to floating diffusion FD and receives reset voltage RD, and includes a gate structure that is controlled by reset gate signal RG. Transistor M1 includes an n-type channel region 1112A_{M1} that is disposed in p-well region 1159A immediately below reset transistor RT and includes a gate structure connected to floating diffusion FD, a drain structure connected to system voltage VOD, and a source structure connected to a drain structure of transistor M2 and a gate structure of transistor M3. Transistor M2 includes an n-type channel region 1112A_{M2} that is disposed in p-well region 1159A immediately below transistor M1 and includes gate structure and source structures connected to ground. Transistor M3 includes an n-type channel region 1112A_{M3} that is disposed in p-well region 1159A immediately below transistor M2 and includes a drain structure connected to system voltage VOD, and a source structure that serves to transmit an output signal OS_{1100A} of pixel 1100A to an associated analog-to-digital converter by way of a metal pad or solder ball/bump 1106 in an arrangement similar to that shown and described with reference to FIG. 10C. Note that the metal pad for OS may lie at a location away from the center of pixel 1100A, and, in one embodiment, may overlay part of one, or more, adjacent pixels.

In one embodiment, reset transistor RT is controlled to discharge floating diffusion FD to reset voltage RD using a reset gate voltage RG that is sufficiently positive to turn on reset transistor RT. RD should be more positive than the voltages applied to the various pixel gates (e.g., resistive gate 1151 and summing gate 1153, described above with reference to FIGS. 11A and 11B). For example, referring to the example shown in FIG. 12B in which summing gate 1153 is controlled using 10V, reset drain voltage RD might have a voltage value between about 15V and 20V. It is necessary to periodically turn on reset transistor RT to discharge the electrons that have accumulated in floating diffusion FD. When the incident electron current hitting the pixel is small, it may not be necessary to discharge (reset) the floating diffusion every time that the pixel is read out. When the incident current is high, floating diffusion FD may need to be reset every pixel clock period.

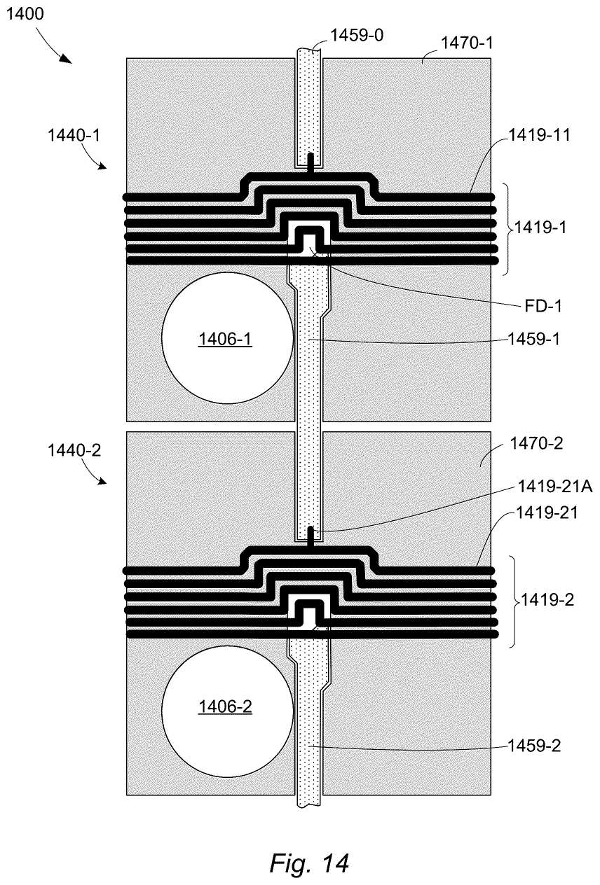

FIG. 14 shows a partial simplified exemplary sensor 1400 that is arranged in accordance with another embodiment of the present invention, and illustrates an alternative layout pattern in which the p-well region 1459-1 of pixel 1440-1 extends into the space otherwise occupied by an adjacent pixel 1440-2, and at least one control signal utilized by pixel 1440-1 is connected to a signal line 1419-21 passing over adjacent pixel 1440-2. The p-well regions and signal lines discussed in this example are formed and function in a manner similar to p-well region 1159 and signal lines 1019 discussed in additional detail above with reference to FIGS. 11A and 10A, respectively. Note that metal line bundles 1419-1 and 1419-2 extend over all other structures, are separated from underlying polysilicon structures (e.g., resistive gate 1470-1 or resistive gate 1470-2) by a borophosphosilicate glass layer or other dielectric material, and are connected by way of metal vias (not shown) to the underlying structures. Note also that several structures of pixels 1440-1 and 1440-2 that are described above are omitted in FIG. 14 for clarity and brevity.

As mentioned above, the amorphous or polycrystalline gate structure utilized to generate the resistive gate (and any additional gates such as summing gate 1153, discussed above) in each pixel essentially entirely covers the pixel area except for the central region (i.e., to allow for access to the floating diffusion) and the area in which a p-well is formed. In the example described above with reference to FIGS. 11A and 11B, p-well region 1159 is entirely disposed within the square-shaped boundary of each pixel, so the resistive and summing gates extend entirely around the remaining perimeter of pixel 1100. However, in some cases the M3 amplifier transistors requires a width that causes it to extend beyond the lower pixel boundary.

To accommodate the extended M3 transistor shape, the pixels of sensor 1400 are configured to share a portion of their space with an adjacent pixel. Specifically, to provide space for both its own elongated p-well region 1459-1 and the portion of p-well region 1459-0 extending downward from the pixel above (not shown), resistive gate structure 1470-1 of pixel 1440-1 is formed in a generally “H” shaped pattern. Similarly, resistive gate structure 1470-2 of pixel 1440-2 is formed in the same “H” shaped pattern to accommodate the lower portion of p-well 1459-1 and the upper portion of p-well region 1459-2.

As also discussed above, pixels in each row of sensor 1400 share common signal lines that extend along the entire row to a peripherally positioned control circuit (not shown). In the case shown in FIG. 14, signal line bundle 1419-1 extends over the row including pixel 1440-1, and signal line bundle 1419-2 extends over the row including pixel 1440-2. Due to the extension of the p-well regions into adjacent pixels, in some cases it becomes efficient to provide signal connections from the signal line bundle extending over an adjacent pixel. For example, signal line 1419-21 is connected by way of conductor 1419-21A to a transistor structure (not shown) disposed in p-well region 1459-1, whereby a signal (e.g., 0V/ground) is provided to pixel 1440-1 from signal bundle 1419-2 passing over adjacent pixel 1440-2. Similarly, signal line 1419-11 of signal bundle 1419-1 provides a signal to a transistor structure (not shown) disposed in p-well region 1459-0.

FIG. 14 also depicts a preferred position of solder bumps/balls 1406-1 and 1406-2 in pixels 1440-1 and 1440-2 (i.e., in the lower left quarter of each pixel area). Note that the depicted sizes of solder bumps/balls 1406-1 and 1406-2 in pixels 1440-1 and 1440-2 are generally accurate for a 250 μm nominal lateral (e.g., diagonal) pixel size and a standard solder bump/ball. In alternative embodiments with different sized pixels or different sized solder balls or bumps, the relative sizes of the pad and the pixel could differ significantly from those illustrated in FIG. 14.

In an embodiment, the electron detectors described herein may also detect X-rays. If an X-ray emitted by the sample has enough energy, such as an energy of about 1 keV or higher, it may generate enough electrons when absorbed in the electron sensor to be detected.

The systems and methods described herein may be used with any of the systems and methods described in U.S. Published Patent Application 2014/0151552, entitled “Tilt-Imaging Scanning Electron Microscope” and filed by Jiang et al. on Mar. 18, 2013, U.S. Published Patent Application 2013/0341504, entitled “Auger Elemental Identification Algorithm”, and filed by Neill et al. on Jun. 7, 2013, U.S. Published Patent Application 2011/0168886, entitled “Charged-particle energy analyzer” and filed by Shadman et al. on Mar. 17, 2011, and U.S. Published Patent Application 2010/0208979, entitled “Use of design information and defect image information in defect classification” and filed by Abbott et al. on Feb. 16, 2009. All these applications are incorporated by reference herein.

In one embodiment, the electron-sensor pixel includes a boron layer disposed on the second surface of the epitaxial silicon layer. For example, in embodiments in which the floating diffusion (FD) is implemented by a VCVFD structure, the sensor may also include a boron coating (such as boron coating 1160 shown in FIGS. 11A and 11B), which can be important for electron detectors and for DUV, VUV, and EUV detectors. In another embodiment, the electron-sensor pixel includes a beryllium coating disposed on the second surface of the epitaxial silicon layer in order to block most electrons from reaching the epitaxial silicon layer, while allowing most X-rays to reach the layer. In an additional embodiment, the electron-sensor pixel includes a thin foil disposed in front of the second surface of the epitaxial silicon layer. For example, a beryllium coating or thin foil in front of the sensor (wherein “thin” may be defined in this context as about 5 μm-100 μm thick) would be good for X-ray detectors to block electrons. In some such embodiments, boron coating 1160 shown in FIGS. 11A and 11B may instead be replaced by a beryllium coating or thin foil, or a beryllium coating or thin foil may be used in addition to boron coating 1160.

The electron-sensor pixel, electron sensor, and electron beam system embodiments described above may be further configured as described herein. For example, in one embodiment, the silicon layer is a silicon epitaxial layer. In one such embodiment, the silicon epitaxial layer includes intrinsic or p-type doped silicon with a dopant concentration less than 10¹⁴ cm⁻³.

In another embodiment of the electron-sensor pixel where floating diffusion (FD) is implemented as a VCVFD, the VCVFD source region and the n-type buried channel layer are doped with the same polarity, and the VCVFD source region has a dopant concentration equal to or higher than a dopant concentration in the n-type buried channel layer. In some embodiments, the VCVFD source region is connected to a charge reset structure. In a further embodiment, wherein the VCVFD channel region and the n-type buried channel layer are doped with the same polarity. In an additional embodiment, the silicon layer is a silicon epitaxial layer, and the p-type electron-sensitive layer has a dopant concentration at least ten times higher than a dopant concentration of the silicon epitaxial layer.

In some embodiments, the electron-sensor pixel is one of multiple electron-sensor pixels configured as a two-dimensional array of pixels in an image sensor. Such an array of pixels may be configured as shown in FIGS. 6A, 6B, and 6C, but instead of the VCVFD being positioned at one end of a column of pixels, each pixel would include its own VCVFD structure as described further above.

Further modifications and alternative embodiments of various aspects of the invention will be apparent to those skilled in the art in view of this description. For example, image sensors, systems that include image sensors, and methods for determining information for a specimen are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. An image sensor, comprising:
a silicon layer configured to generate electron-hole pairs when light is incident on a light-sensitive area of the silicon layer;
circuits formed on a first side of the silicon layer, wherein the circuits comprise a channel and first gate electrodes configured to control electron accumulation in the channel in response to generation of the electron-hole pairs; and
a sensing node electrically connected to the circuits, formed on the first side of the silicon layer adjacent to the circuits and outside of the light-sensitive area, and formed by a Voltage-Controlled Variable Floating Diffusion (VCVFD) structure, wherein the VCVFD structure comprises:
a source region and a channel region, wherein the source region of the VCVFD structure is connected to the channel of the circuits and an output circuit of the image sensor; and
a second gate electrode adjacent to the source region and configured to control a variable capacitance of the VCVFD structure via voltage applied to the second gate electrode by an electrical connection to the second gate electrode,
wherein the VCVFD structure is configured to convert a charge responsive to the electron accumulation to a voltage proportional to an amount of the charge and dependent on the variable capacitance, and
wherein the output circuit is configured to generate output responsive to the voltage output by the VCVFD structure.

2. The sensor of claim 1, wherein the image sensor is configured as a charge-coupled device.

3. The sensor of claim 1, wherein the image sensor is configured as a backside illuminated charge-coupled device.

4. The sensor of claim 1, wherein the image sensor is configured as a charge-coupled device configured to function as a time-delay integration sensor.

5. The sensor of claim 1, wherein the circuits are configured as charge-coupled device circuits.

6. The sensor of claim 1, wherein the circuits are configured as metal-oxide-semiconductor field-effect transistors (MOSFETs).

7. The sensor of claim 1, wherein the silicon layer is a silicon epitaxial layer.

8. The sensor of claim 1, wherein the silicon layer is a silicon epitaxial layer, and wherein the silicon epitaxial layer comprises intrinsic or p-type doped silicon with a dopant concentration less than 10¹⁴ cm⁻³.

9. The sensor of claim 1, wherein the channel of the circuits comprises an n-type doped buried channel.

10. The sensor of claim 1, wherein the source region of the VCVFD structure and the channel of the circuits are doped with the same polarity, and wherein the source region of the VCVFD structure has a dopant concentration equal to or higher than a dopant concentration in the channel of the circuits.

11. The sensor of claim 1, wherein the source region of the VCVFD structure is further connected to a charge reset structure in the image sensor.

12. The sensor of claim 1, wherein the channel region of the VCVFD structure and the channel of the circuits are doped with the same polarity.

13. The sensor of claim 1, wherein the silicon layer is a silicon epitaxial layer, wherein the image sensor further comprises a thin p-type layer with a dopant concentration at least ten times higher than a dopant concentration of the silicon epitaxial layer, and wherein the thin p-type layer is disposed on a second side of the silicon epitaxial layer opposite to the first side.

14. The sensor of claim 1, wherein the image sensor further comprises an antireflection layer disposed on a second side of the silicon layer opposite to the first side.

15. The sensor of claim 1, wherein the circuits are configured as a two-dimensional array of pixels.

16. The sensor of claim 1, wherein the circuits are configured as multiple columns of pixels comprising at least first and second columns of pixels, wherein the at least first and second columns of pixels comprise one or more pixels, wherein the sensing node is one of multiple sensing nodes in the image sensor, wherein the multiple sensing nodes comprise at least first and second sensing nodes, and wherein the first and second sensing nodes are electrically connected to all of the one or more pixels in the first and second columns of pixels, respectively.

17. The sensor of claim 1, wherein the circuits are configured as multiple columns of pixels comprising at least first and second columns of pixels, wherein the at least first and second columns of pixels comprise one or more pixels, and wherein the sensing node is electrically connected to the one or more pixels in the first and second columns of pixels.

18. The sensor of claim 1, wherein the channel region of the VCVFD structure is configured as an n-type buried channel.

19. The sensor of claim 1, wherein the channel region of the VCVFD structure is configured as an n-type surface channel.

20. The sensor of claim 1, wherein the VCVFD structure further comprises a drain region connected to the channel region of the VCVFD structure, and wherein the source region and the drain region of the VCVFD structure are electrically connected.

21. The sensor of claim 1, wherein the circuits are configured as pixels comprising at least first and second pixels, wherein the sensing node is electrically connected to the first and second pixels, and wherein the image sensor or a computer subsystem is configured to calibrate the sensing node thereby calibrating the first and second pixels.

22. The sensor of claim 1, wherein the image sensor is positioned in an inspection system so that the light incident on the light-sensitive area is light from a specimen being inspected by the inspection system, and wherein the inspection system is configured for detecting defects on the specimen based on the output generated by the output circuit of the image sensor.

23. A system configured for determining information for a specimen, comprising:
an illumination subsystem configured for directing light generated by a light source to a specimen;
an image sensor positioned in a path of light from the specimen and comprising:
a silicon layer configured to generate electron-hole pairs when the light from the specimen is incident on a light-sensitive area of the silicon layer;
circuits formed on a first side of the silicon layer, wherein the circuits comprise a channel and first gate electrodes configured to control electron accumulation in the channel in response to generation of the electron-hole pairs; and
a sensing node electrically connected to the circuits, formed on the first side of the silicon layer adjacent to the circuits and outside of the light-sensitive area, and formed by a Voltage-Controlled Variable Floating Diffusion (VCVFD) structure, wherein the VCVFD structure comprises:
a source region and a channel region, wherein the source region of the VCVFD structure is connected to the channel of the circuits and an output circuit of the image sensor; and
a second gate electrode adjacent to the source region and configured to control a variable capacitance of the VCVFD structure via voltage applied to the second gate electrode by an electrical connection to the second gate electrode,
wherein the VCVFD structure is configured to convert a charge responsive to the electron accumulation to a voltage proportional to an amount of the charge and dependent on the variable capacitance, and
wherein the output circuit is configured to generate output responsive to the voltage output by the VCVFD structure; and
a computer subsystem configured for determining information for the specimen based on the output.

24. The system of claim 23, wherein the system is further configured as an inspection system, and wherein the information for the specimen comprises information for defects detected on the specimen based on the output.

25.-36. (canceled)
